(19) United States
(12) Patent Application Publication
(10) Pub. No.: US 2017/0184640 A1
(43) Pub. Date: Jun. 29, 2017

(54) Systems, Methods, and Software for Planning, Simulating, and Operating Electrical Power Systems

(71) Applicant: Carnegie Mellon University, Pittsburgh, PA (US)

(72) Inventors: Lawrence Pileggi, Pittsburgh, PA (US); David M. Bromberg, Pittsburgh, PA (US); Xin Li, Pittsburgh, PA (US); Gabriela Hug, Pittsburgh, PA (US); Amritanshu Pandey, Pittsburgh, PA (US); Marko Jereminov, Orangeburg, SC (US)

(21) Appl. No.: 15/456,341

(22) Filed: Mar. 10, 2017

Related U.S. Application Data
(63) Continuation-in-part of application No. PCT/US15/49700, filed on Sep. 11, 2015.
(60) Provisional application No. 62/071,052, filed on Sep. 12, 2014.
(60) Provisional application No. 62/390,516, filed on Mar. 31, 2016.
(60) Provisional application No. 62/496,725, filed on Oct. 26, 2016.

(51) Int. Cl. G01R 19/25; G06F 17/50; H02J 3/38; G01R 31/34

(52) U.S. Cl. CPC G01R 19/2513; G01R 31/34; G06F 17/5036; H02J 3/383; H02J 3/386

(57) ABSTRACT

An approach to modeling the nonlinear steady-state behavior of an electrical power grid in terms of equivalent circuits with currents and voltages as state variables is provided. Current and voltage conservation equations are formulated with circuit-theoretic algorithms that offer demonstrably superior robustness relative to traditional approaches. Generalized bus and line models are accommodated by the equivalent circuit-based approach, allowing for simulation of physical models not compatible with traditional methods. Unbalanced three-phase systems are handled without loss of generality. The provided methods allow for robust, efficient power flow simulation for contingency analysis, power system planning, power system design, power system control, component configurations and operating conditions, real-time scheduling, and optimization, among other applications.

### RELATED APPLICATION DATA

This application is a continuation-in-part of International Patent Application PCT/US15/49700, filed on Sep. 11, 2015, and titled “SYSTEMS, METHODS, AND SOFTWARE FOR PLANNING, SIMULATING, AND OPERATING ELECTRICAL POWER SYSTEMS”, which claims the benefit of priority of U.S. Provisional Patent Application Ser. No. 62/071,052, filed on Sep. 12, 2014, and titled “Methods and systems for simulation of electrical power grids in terms of AC voltage and current state variables”. This application also claims the benefit of priority of each of U.S. Provisional Application Ser. No. 62/390,516, filed on Mar. 31, 2016, and titled “Method of steady-state analysis of power system harmonics using equivalent split-circuit models”, and U.S. Provisional Patent Application Ser. No. 62/496,725, filed on Oct. 26, 2016, and titled “Power Flow Robustness via Circuit Simulation Methods”. Each of the foregoing applications is incorporated by reference herein in its entirety.

### FIELD OF THE INVENTION

The present invention generally relates to the field of electrical power planning, simulation, generation, transmission, and distribution. In particular, the present invention is directed to systems, methods, and software for planning, simulating, and operating electrical power systems.

### BACKGROUND

The steady state behavior of an electrical power grid for transmission of electricity is traditionally modeled using power flow analysis. Power flow is based on nonlinear balance equations of real and reactive power that are solved iteratively to calculate the voltage magnitude, voltage phase, and power at every bus in the system. Even for balanced systems, this method suffers from poor robustness, where the accuracy (and convergence) of a simulation is strongly dependent on an initial guess of the system's operation, the system configuration, and the power demanded by the loads. Furthermore, formulating the system equations in terms of power balance with voltage magnitude and angle variables limits the generality of models that can be simulated.

These single phase power flow methods based on iteratively solving the power balance equations were first conceived of decades ago and remain the standard for simulating transmission-level power grids, where perfect phase balance is assumed. At the distribution level, however, the loads are unbalanced, which necessitates the use of an algorithm that accurately models all phases in the power system. The methods currently used to simulate these unbalanced three-phase networks suffer from poor convergence and robustness as well, particularly for system configurations that represent abnormal behavior due to failure. Most importantly, these distribution formulations are mathematically derived, not based on physical models, which can sometimes fail to produce natural governing power system (circuit) equations. For example, analyzing a nonlinear open-Wye connected unbalanced PQ load with fixed-point iteration, which is the method proposed for many distribution problems, results in a “physical model” corresponding to three nonlinear independent current sources that are connected to a “floating node.” This represents an “unnatural circuit” configuration that is recognized to have convergence problems. Distributed energy resources such as solar arrays and wind generators are also not easily incorporated into this simulation environment. Accordingly, new methods for dealing with these issues in a more flexible and robust fashion are desirable.

### SUMMARY OF THE DISCLOSURE

In one implementation, the present disclosure is directed to a method of simulating and operating an electrical power system. The method includes formulating current and voltage conservation equations from which power flow can be derived by conceptually splitting a circuit representation of the electrical power system into an equivalent circuit representation, the equivalent circuit representation including: a real sub-circuit including all real-valued voltages and currents; and an imaginary sub-circuit containing all imaginary-valued voltages and currents, wherein the real sub-circuit and imaginary sub-circuit are coupled via controlled voltage and current sources; solving the current and voltage conservation equations to produce a power flow solution; and operating the electrical power system in accordance with the power flow solution.

In another implementation, the present disclosure is directed to a machine-readable storage medium containing machine-executable instructions for performing a method of simulating and operating an electrical power system. The machine-executable instructions include a first set of machine-executable instructions for formulating current and voltage conservation equations from which power flow can be derived by conceptually splitting a circuit representation of the electrical power system into an equivalent circuit representation, the equivalent circuit representation including: a real sub-circuit including all real-valued voltages and currents; and an imaginary sub-circuit containing all imaginary-valued voltages and currents, wherein the real sub-circuit and imaginary sub-circuit are coupled via controlled voltage and current sources; a second set of machine-executable instructions for solving the current and voltage conservation equations to produce a power flow solution; and a third set of machine-executable instructions for operating the electrical power system in accordance with the power flow solution.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a flow diagram illustrating a method of simulating and operating an electrical power system;

FIG. 2A illustrates an exemplary three bus network with generator, slack bus, and load;

FIG. 2B illustrates an equivalent circuit model of the three bus network of FIG. 2A;

FIG. 3 is a flow diagram illustrating the Newton-Raphson algorithm;

FIG. 4 illustrates a split circuit model of the three bus system of FIG. 2A;

FIG. 5 illustrates a generator equivalent circuit model using current sources;

FIG. 6 illustrates real and imaginary circuit models for a transformer;

FIG. 7 is a block diagram of a grid-connected solar power system;

FIG. 8 illustrates an equivalent circuit model of the solar power system of FIG. 7;

FIG. 9 illustrates a linearized circuit model of the solar power system of FIG. 7;

FIG. 10 is a directed graph representation of the circuit model of FIG. 3;

FIG. 11 is a graph illustrating decreases in Newton-Raphson method residue in each iteration of solving power flow for an ill-conditioned 11-bus system using methods of the present disclosure;

FIG. 12 illustrates an exemplary two-bus system;

FIG. 13 is a graph of regions of convergence for initial seeds used to solve power flow for the two-bus system of FIG. 12 using traditional power flow methods;

FIG. 14 is a graph of regions of convergence for initial seeds used to solve power flow for the two-bus system of FIG. 12 using a current-voltage tree-link analysis simulator made in accordance with the present disclosure;

FIG. 15 is a graph of regions of convergence for initial seeds used to solve power flow for the two-bus system of FIG. 12 using a current-voltage tree-link analysis simulator made in accordance with the present disclosure when power stepping is applied;

FIG. 16 is a graph of stack bus power vs. generated solar power for an IEEE 14-bus system in which the generator is replaced with the equivalent circuit model for a solar power system of FIG. 7;

FIG. 17 illustrates a complete split circuit model of a slack bus generator connected in a grounded Wye configuration;

FIG. 18 illustrates a complete split circuit model, including both real and imaginary sub-circuits, of one phase of a three-phase transmission line;

FIG. 19 illustrates a complete split circuit model of a neutral line of a three-phase transmission line;

FIG. 20 illustrates an unnatural circuit model of an induction motor;

FIG. 21 illustrates an equivalent split circuit model of an induction motor;

FIG. 22 illustrates an equivalent split circuit model of an open Wye connected constant impedance load;

FIG. 23 illustrates an equivalent split circuit model of an ideal center-tapped transformer;

FIG. 24 illustrates a schematic diagram of an IEEE 4-bus Wye-Delta center-tapped transformer test case circuit;

FIG. 25 illustrates an equivalent split circuit model of the IEEE 4-bus Wye-Delta center-tapped transformer test case circuit;

FIG. 26 is a block diagram of a computing system that can be used to implement any one or more of the methodologies disclosed herein and any one or more portions thereof;

FIG. 27A is a voltage profile for maximum bus voltage in a 2383-bus system without variable limiting;

FIG. 27B is a voltage profile for maximum bus voltage in a 2383-bus system with variable limiting;

FIG. 28 is a graph of voltage magnitude versus real power for bus 3 voltage for an IEEE 14-bus test system with increasing load factors with and without circuit simulation methods;

FIG. 29 contains two graphs showing results of power flow results for, respectively, a 2869-bus test system and a 9241-bus test system with and without circuit simulation techniques;

FIG. 30 is a diagram illustrating a nonlinear time-domain diode equivalent circuit;

FIG. 31 is a diagram illustrating the DC and m^{th} harmonic real and imaginary diode equivalent circuits;

FIG. 32 is a diagram illustrating an m^{th} harmonic real and imaginary nonlinear inductor equivalent circuit;

FIG. 33 is a diagram illustrating a DC and m^{th} harmonic transmission line equivalent split circuit;

FIG. 34 is a diagram illustrating an m^{th} harmonic circuit of a full bridge rectifier;

FIG. 35 is a diagram illustrating a per-phase harmonic equivalent circuit of a transformer with incorporated magnetic core saturation characteristics;

FIG. 36 is a diagram illustrating an m^{th} harmonic circuit corresponding to the harmonic equivalent circuit of FIG. 35;

FIG. 37 is a line diagram of a simulated power system;

FIG. 38A is a graph of the calculated right side of the harmonic spectrum of load voltage;

FIG. 38B is a graph of the calculated right side of the harmonic spectrum of the line current;

FIG. 39A is a graph of voltage versus time illustrating waveforms obtained from steady-state response simulations of a system; and

FIG. 39B is a graph of transmission line current versus time illustrating waveforms obtained from transient simulation of the system of FIG. 39A.

### DETAILED DESCRIPTION

Aspects of the present disclosure include systems, methods, and software for planning, simulating, and operating electrical power systems. At a high level, aspects of the present disclosure are directed to generating power flow solutions. In various embodiments, these solutions and/or the means for arriving at them provided herein can be used to plan, simulate, and/or operate new or existing power systems with more efficiency and robustness than most, if not all, previously known methods. Exemplary embodiments illustrating these and other aspects of the present disclosure are described below in the context of several specific examples.

An aspect of the present disclosure models a power system by splitting the circuit representation of the power grid into its real and imaginary component. Current and voltage conservation equations are formulated from the split circuit that defines the power flow and other power system analyses. The formulated current and voltage conservation equations from the split circuit representation are a superset of current conservation equations generated by another method, namely, the “Current Injection Method” that is based on mathematically deriving the current mismatch equations at each bus (node) in the power system to balance the complex power at that bus (node). The Current Injection Method does not, however, enable the generalized use of combinations of voltage and current to represent the components of the power system. For example, it is shown within this application, that the voltage-based representation for a generator bus cannot be formulated within the current injection method. Details concerning the Current Injection Method can be found in V. M. da Costa, N. Martins, J. L. R. Pereira, “Developments in the Newton Raphson Power Flow Formulation based on Current Injections”, IEEE Transactions on Power Systems, Vol. 14, No. 4, November 1999, which is incorporated by reference herein for its descriptions of the Current Injection Method.

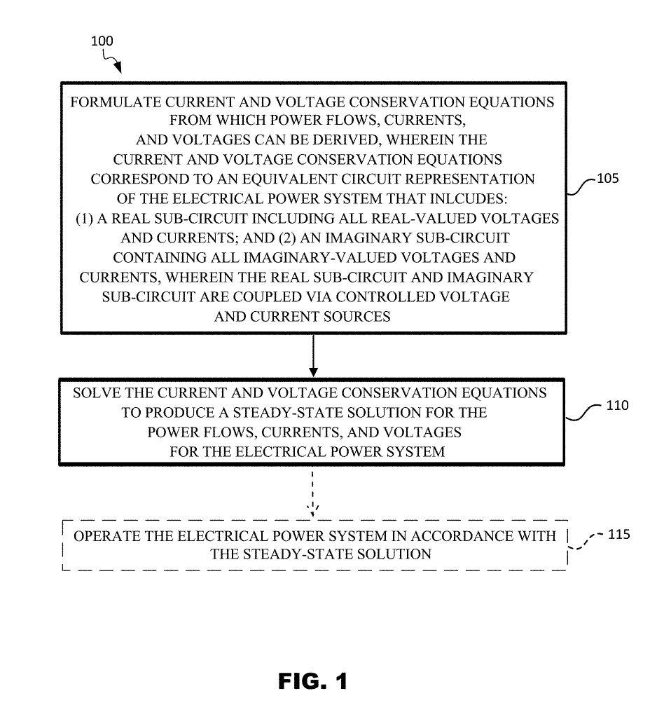

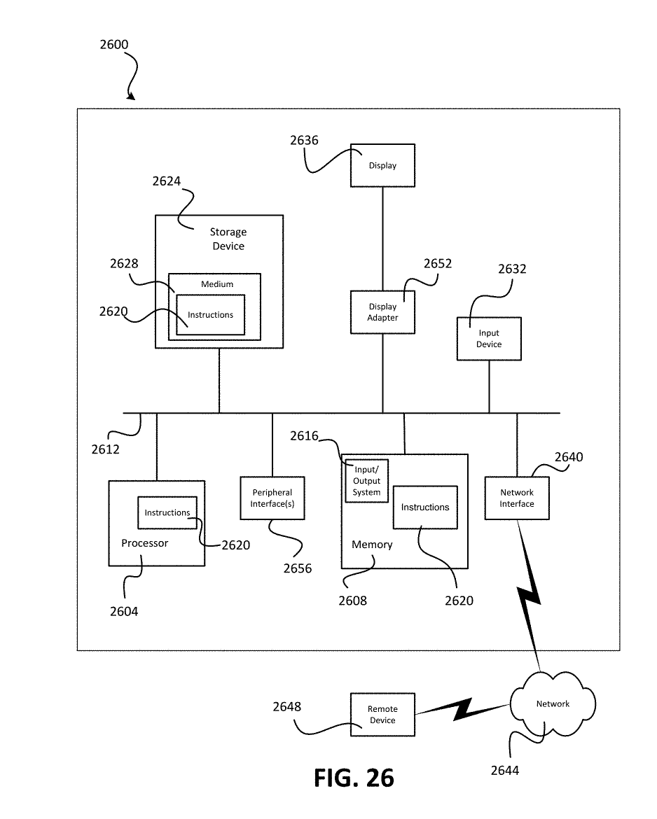

Referring now to the drawings, FIG. 1 illustrates an exemplary method 100 that is in accordance with various aspects of the present invention. At step 105, method 100 includes formulating, for an electrical power system, current and voltage conservation equations from which power flows, currents, and voltages within the electrical power system can be derived. The current and voltage conservation equations correspond to an equivalent circuit representation of the electrical power system that includes: (1) a real sub-circuit including all real-valued voltages and currents; and (2) an imaginary sub-circuit containing all imaginary-valued voltages and currents, wherein the real sub-circuit and imaginary sub-circuit are coupled via controlled voltage and current sources. The formulation of the current and voltage conservation equations can be performed with the assistance of a power flow analyzer, which may be any type of equipment, ranging from a general purpose computer system (see, e.g., computer system 2600 of FIG. 26) programmed with the appropriate power flow analysis algorithms to specialized equipment provided solely for the purpose of automating the power flow analysis process disclosed herein. The current and voltage conservation equations are fundamentally mathematical in nature, and, as such, those skilled in the art will readily appreciate that formulating the current and voltage conservation equations can be effected in any suitable manner, including manners that do not require derivation of split-circuit models. Generally, what is required is that the current and voltage conservation equations mathematically represent such models, regardless of how they are formulated.

At step 110, method 100 includes solving the current and voltage conservation equations to produce a steady-state solution for the power flows, currents, and voltages for the electrical power system. Generally, this step is practiced by causing the power flow analyzer to execute power flow algorithms that contain the current and voltage conservation equations. The causing of the power flow analyzer to solve the current and voltage conservation equations can be brought about in any manner known in the art, such as by receiving a user input that instructs the power flow analyzer to execute the power flow algorithms. At optional step 115, method 100 may include operating the electrical power system in accordance with the steady-state solution produced at step 110. In some embodiments, the steady-state solution produced at step 110 may be used for purposes other than operating an electrical power system, such as for planning and/or designing a new power system or monitoring the state of the system in normal state or for any conceivable contingency state. Other uses of the steady-state solution determined at step 105 are described in Section VII, below. Indeed, the applications to which the broad and novel principles in steps 105 and 110 are many. As noted above, steps 105 and 110 may be performed automatedly. Optional step 115 may also be performed automatedly by a power system controller that may include the power flow analyzer as well as equipment and algorithms for implementing the steady-state solution on the electrical power system. Those skilled in the art will readily understand how to integrate a power flow analyzer of the present disclosure into a power system controller or other system, such as a power system simulator or an energy management system, among others. Each of steps 105, 110, and 115 and many others are described in detail herein below.

### I. Split Circuit Model

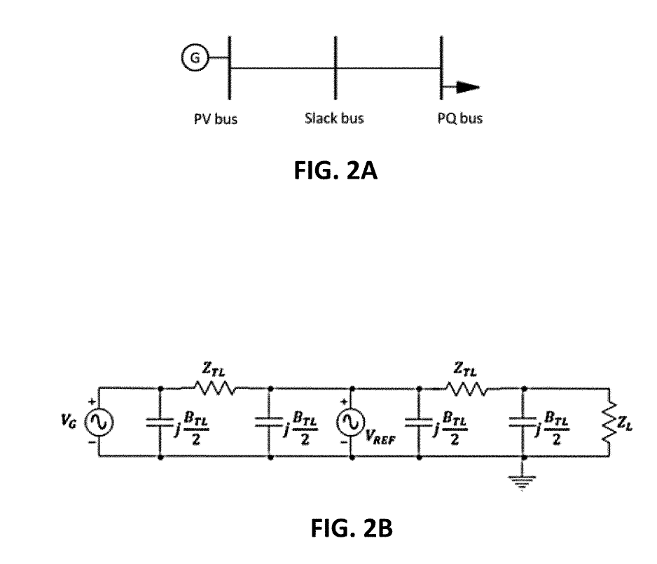

To begin, an equivalent circuit model of a power grid with currents and voltages as the state variables is constructed. Consider the three bus network shown in FIG. 2A. The buses and transmission lines are replaced with circuit elements (voltage sources, impedances, etc.), as shown in FIG. 2B. Here, Z_{TL}=R_{TL}+jX_{TL} is the impedance of the transmission line, B_{TL} is the shunt susceptance of the transmission line, and Z_{L} is the load impedance. The generator voltage is a complex function of the generator current; similarly, the load current is a complex function of the load voltage.

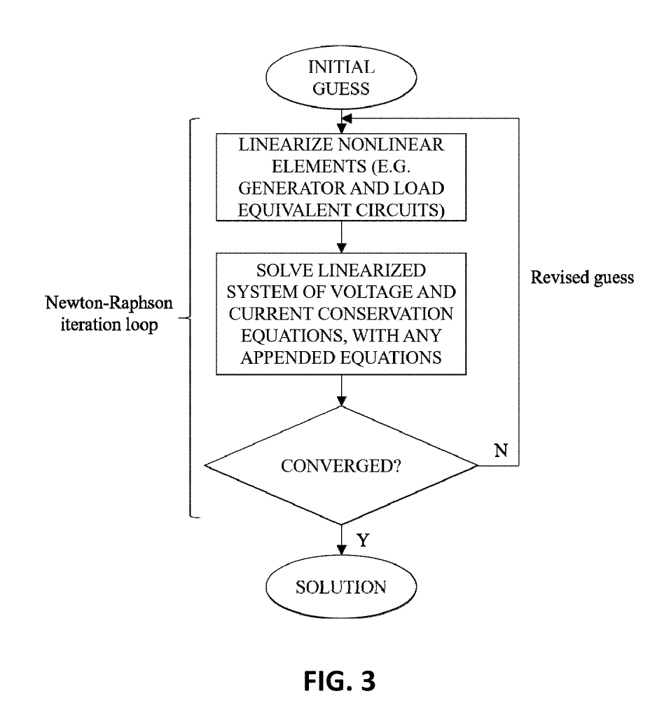

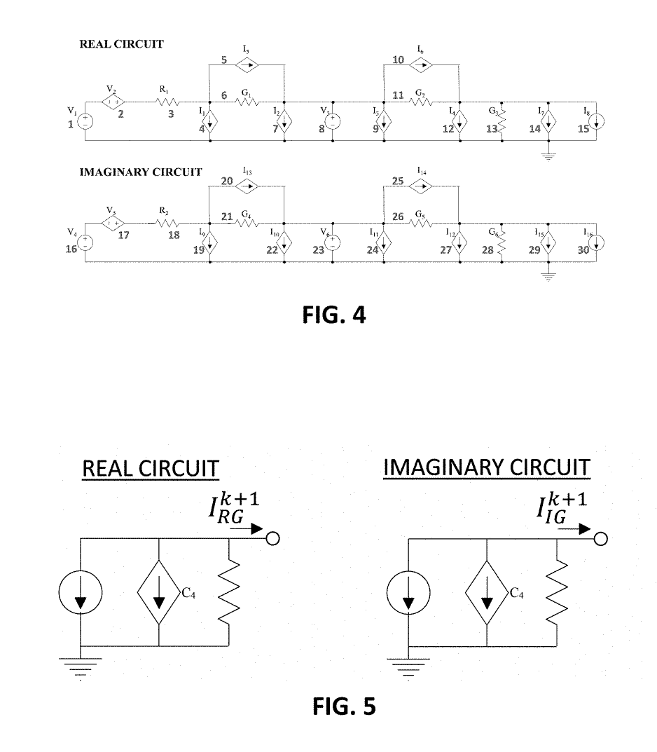

The present inventors recognized that it would be useful to be able to apply the well-known Newton-Raphson (NR) algorithm to solve this nonlinear circuit, an algorithm which involves taking first-order Taylor expansions (first-order derivatives) on the non-linear equations. FIG. 3 illustrates the flow of the Newton-Raphson algorithm applied to the power flow problem. An initial guess is provided; on every iteration, the nonlinear elements are linearized via a Taylor expansion. The linearized circuit equations are solved, and the variables are until the solution of a given iteration is negligibly small relative to the previous iteration. However, the complex functions describing the electrical power system (e.g., generator voltage as a function of current) are not analytical, and hence, not differentiable. Accordingly, in this case, NR cannot be directly applied to the circuit in FIG. 2B. A key insight of the present inventors, however, is that the circuit can be split into two circuits, one real and one imaginary, coupled by controlled sources (see FIG. 4, which includes branch numbers, and Table I, which specifies values for each component). For example, consider the controlled source V₂ in the schematic. The voltage of this source is controlled by the current flowing through its counterpart in the imaginary circuit, i.e., V₅. As a consequence of splitting the circuit, it is no longer necessary to solve complex functions; the actual generator voltage V_{G}, for example, is the sum of the voltages in the real circuit (V_{RG}) and imaginary circuit (V_{IG}) at the generator node (V_{G}=V_{RG}+jV_{IG}). NR is then used to handle the non-linearities. The following sections describe how the circuit elements can be derived.

TABLE I
COMPONENT VALUES/EXPRESSIONS FOR THE CIRCUIT
OF FIG. 4

| REAL CIRCUIT | | IMAGINARY CIRCUIT | |
|---|---|---|---|
| Com- | | Com- | |
| ponent | Value | ponent | Value |
| V₁ | V_{RG}^{k} | V₄ | V_{IG}^{k} |
| | $- \frac{\partial {V}_{RG}}{\partial {I}_{IG}} {\vert}_{{I}_{RG}^{k} , {I}_{IG}^{k}} ( {I}_{IG}^{k} )$ | | $- \frac{\partial {V}_{IG}}{\partial {I}_{RG}} {\vert}_{{I}_{RG}^{k} , {I}_{IG}^{k}} ( {I}_{RG}^{k} )$ |
| | $- \frac{\partial {V}_{RG}}{\partial {I}_{RG}} {\vert}_{{I}_{RG}^{k} , {I}_{IG}^{k}} ( {I}_{RG}^{k} )$ | | $- \frac{\partial {V}_{IG}}{\partial {I}_{IG}} {\vert}_{{I}_{RG}^{k} , {I}_{IG}^{k}} ( {I}_{IG}^{k} )$ |
| V₂ | $\frac{\partial {V}_{RG}}{\partial {I}_{IG}} {\vert}_{{I}_{RG}^{k} , {I}_{IG}^{k}} ( {I}_{IG}^{k + 1} )$ | V₅ | $\frac{\partial {V}_{IG}}{\partial {I}_{RG}} {\vert}_{{I}_{RG}^{k} , {I}_{IG}^{k}} ( {I}_{RG}^{k + 1} )$ |
| V₃ | V_{REF}cosθ | V₆ | V_{REF}sinθ |
| R₁ | $\frac{\partial {V}_{RG}}{\partial {I}_{IG}} {\vert}_{{I}_{RG}^{k} , {I}_{IG}^{k}}$ | R₂ | $\frac{\partial {V}_{IG}}{\partial {I}_{IG}} {\vert}_{{I}_{RG}^{k} , {I}_{IG}^{k}}$ |
| I₁ | $- \frac{{B}_{TL}}{2} ( {V}_{19} )$ | I₉ | $\frac{{B}_{TL}}{2} ( {V}_{4} )$ |
| I₂ | $- \frac{{B}_{TL}}{2} ( {V}_{22} )$ | I₁₀ | $\frac{{B}_{TL}}{2} ( {V}_{7} )$ |
| I₃ | $- \frac{{B}_{TL}}{2} ( {V}_{24} )$ | I₁₁ | $\frac{{B}_{TL}}{2} ( {V}_{9} )$ |
| I₄ | $- \frac{{B}_{TL}}{2} ( {V}_{27} )$ | I₁₂ | $\frac{{B}_{TL}}{2} ( {V}_{12} )$ |
| I₅ | $\frac{{X}_{TL}}{{R}_{TL}^{2} + {X}_{TL}^{2}} ( {V}_{20} )$ | I₁₃ | $- \frac{{X}_{TL}}{{R}_{TL}^{2} + {X}_{TL}^{2}} ( {V}_{5} )$ |
| I₆ | $\frac{{X}_{TL}}{{R}_{TL}^{2} + {X}_{TL}^{2}} ( {V}_{25} )$ | I₁₄ | $- \frac{{X}_{TL}}{{R}_{TL}^{2} + {X}_{TL}^{2}} ( {V}_{10} )$ |
| I₇ | $\frac{\partial {I}_{RL}}{\partial {V}_{IL}} {\vert}_{{V}_{RL}^{k} , {V}_{IL}^{k}} ( {V}_{IL}^{k + 1} )$ | I₁₅ | $\frac{\partial {I}_{IL}}{\partial {V}_{RL}} {\vert}_{{V}_{RL}^{k} , {V}_{IL}^{k}} ( {V}_{RL}^{k + 1} )$ |
| I₈ | I_{RL}^{k} | I₁₆ | I_{IL}^{k} |
| | $- \frac{\partial {I}_{RL}}{\partial {V}_{IL}} {\vert}_{{V}_{RL}^{k} , {V}_{IL}^{k}} ( {V}_{IL}^{k} )$ | | $- \frac{\partial {I}_{IL}}{\partial {V}_{RL}} {\vert}_{{V}_{RL}^{k} , {V}_{IL}^{k}} ( {V}_{RL}^{k} )$ |
| | $- \frac{\partial {I}_{RL}}{\partial {V}_{RL}} {\vert}_{{V}_{RL}^{k} , {V}_{IL}^{k}} ( {V}_{RL}^{k} )$ | | $- \frac{\partial {I}_{IL}}{\partial {V}_{IL}} {\vert}_{{V}_{RL}^{k} , {V}_{IL}^{k}} ( {V}_{IL}^{k} )$ |
| G₁ | $\frac{{R}_{TL}}{{R}_{TL}^{2} + {X}_{TL}^{2}}$ | G₄ | $\frac{{R}_{TL}}{{R}_{TL}^{2} + {X}_{TL}^{2}}$ |
| G₂ | $\frac{{R}_{TL}}{{R}_{TL}^{2} + {X}_{TL}^{2}}$ | G₅ | $\frac{{R}_{TL}}{{R}_{TL}^{2} + {X}_{TL}^{2}}$ |
| G₃ | $\frac{\partial {I}_{RL}}{\partial {V}_{RL}} {\vert}_{{V}_{RL}^{k} , {V}_{IL}^{k}}$ | G₆ | $\frac{\partial {I}_{IL}}{\partial {V}_{IL}} {\vert}_{{V}_{RL}^{k} , {V}_{IL}^{k}}$ |

### I. A. Voltage Source-Based Generator Model

For the generator, the real and imaginary voltage can be expressed as a function of the real and imaginary current (I_{RG} and I_{IG}, respectively). To do this, the following Equations 1 and 2 are solved simultaneously, equations which relate the aforementioned variables to the provided/controlled values of real power (P_{G}) and voltage magnitude (|V_{G}|):

P_{G}=V_{RG}I_{RG}+V_{IG}I_{IG} (1)

|V_{G}|²=V_{RG}²+V_{IG}² (2)

The resulting expressions for voltage are:

$$\begin{matrix}{V}_{RG} = \frac{{P}_{G} {I}_{RG} \pm {I}_{IG} \sqrt{{V}_{G}^{2} ( {I}_{RG}^{2} + {I}_{IG}^{2} ) - {P}_{G}^{2}}}{{I}_{RG}^{2} + {I}_{IG}^{2}} & ( 3 ) \\ {V}_{IG} = \frac{{P}_{G} {I}_{IG} \pm {I}_{RG} \sqrt{{V}_{G}^{2} ( {I}_{RG}^{2} + {I}_{IG}^{2} ) - {P}_{G}^{2}}}{{I}_{RG}^{2} + {I}_{IG}^{2}} & ( 4 )\end{matrix}$$

The correct root to choose for each expression depends on the sign of the reactive power (Q) for the generator; for negative values of Q (generator supplying reactive power), the positive root is selected for V_{RG} and the negative root for V_{IG}. For positive Q, the negative root is chosen for V_{RG} and the positive root for V_{IG}.

The equations are linearized via a first-order Taylor expansion; for example, the expansion of the real voltage at the (k+1)^{th} iteration is:

$${{{V}_{RG}^{k + 1} = \frac{\partial {V}_{RG}}{\partial {I}_{RG}} \vert}_{{I}_{RG}^{k} , {I}_{IG}^{k}} ( {I}_{RG}^{k + 1} ) + \frac{\partial {V}_{RG}}{\partial {I}_{IG}} \vert}_{{I}_{RG}^{k} , {I}_{IG}^{k}} ( {I}_{IG}^{k + 1} ) + {{V}_{RG}^{k} - {\frac{\partial {V}_{RG}}{\partial {I}_{IG}} \vert}_{{I}_{RG}^{k} , {I}_{IG}^{k}} ( {I}_{IG}^{k} ) - \frac{\partial {V}_{RG}}{\partial {I}_{RG}} \vert}_{{I}_{RG}^{k} , {I}_{IG}^{k}} ( {I}_{RG}^{k} ) \qquad ( 5 )$$

The first term represents a non-linear resistor (R₁ in FIG. 4 and Table I), where the voltage across it is proportional to the current through it; the second term represents a dependent voltage source (V₂ in FIG. 4 and Table I), where the controlling variable is the imaginary generator current flowing in the opposite sub-circuit; the final terms represent an independent voltage source (V₁ in FIG. 4 and Table I) based on values from the previous iteration. Symmetric elements in the imaginary sub-circuit (R₂, V₅, V₄) can be derived in an identical manner.

### I. B. Current Source-Based Generator Model

As discussed above, a split circuit model of a generator can be derived in terms of voltage. There is an alternate approach to formulating a generator model, however, whereby equations do not contain square roots. From the definition of apparent power S=VI*:

P_{G}+jQ_{G}=(V_{RG}+jV_{IG})(I_{RG}−jI_{IG}) (6)

Equations 1 and 6 can be solved simultaneously to obtain:

$$\begin{matrix}{I}_{RG} = \frac{{P}_{G} {V}_{RG} + {Q}_{G} {V}_{IG}}{{V}_{RG}^{2} + {V}_{IG}^{2}} & ( 7 ) \\ {I}_{IG} = \frac{{P}_{G} {V}_{IG} - {Q}_{G} {V}_{RG}}{{V}_{RG}^{2} + {V}_{IG}^{2}} & ( 8 )\end{matrix}$$

The generator reactive power Q_{G} is not known, and so it is added as a variable. An extra equation must be added to keep the number of equations and variables consistent; Equation 2 is therefore added as a constraint that ensures the voltage magnitude remains constant and equal to the specified value. This extra equation is appended to the system of voltage and current conservation equations described in a later section.

Taylor expansions of Equations 7 and 8 are taken to linearize the functions and derive equivalent circuit components. For example, the Taylor expansion of the real generator current about the (k+1)^{th} iteration is given by:

$${{{I}_{RG}^{k + 1} = \frac{\partial {I}_{RG}}{\partial {Q}_{G}} \vert}_{{Q}_{G}^{k} , {V}_{RG}^{k} , {V}_{IG}^{k}} ( {Q}_{G}^{k + 1} ) + \frac{\partial {I}_{RG}}{\partial {V}_{RG}} \vert}_{{Q}_{G}^{k} , {V}_{RG}^{k} , {V}_{IG}^{k}} ( {V}_{RG}^{k + 1} ) + {{\frac{\partial {I}_{RG}}{\partial {V}_{IG}} \vert}_{{Q}_{G}^{k} , {V}_{RG}^{k} , {V}_{IG}^{k}} ( {V}_{IG}^{k + 1} ) + {I}_{RG}^{k} - \frac{\partial {I}_{RG}}{\partial {Q}_{G}} \vert}_{{Q}_{G}^{k} , {V}_{RG}^{k} , {V}_{IG}^{k}} ( {Q}_{G}^{k} ) - {\frac{\partial {I}_{RG}}{\partial {V}_{RG}} \vert}_{{Q}_{G}^{k} , {V}_{RG}^{k} , {V}_{IG}^{k}} ( {V}_{RG}^{k} ) - {\frac{\partial {I}_{RG}}{\partial {V}_{IG}} \vert}_{{Q}_{G}^{k} , {V}_{RG}^{k} , {V}_{IG}^{k}} ( {V}_{IG}^{k} ) \qquad ( 9 )$$

The second term represents a conductance, because the real current is proportional to the real voltage; the third term represents a voltage-controlled current source, because the real current is proportional to the imaginary voltage. The remaining terms (except for the first) are all dependent on known values from the previous iteration, so they can be lumped together and represented as an independent current source. FIG. 5 shows an equivalent circuit model for a generator with symmetric elements for the real and imaginary generator current (C₄ indicates coupling between the controlled sources of the real and imaginary sub-circuits).

The first term in Equation 9 is not a true circuit element, as it represents a value of current controlled by reactive power. The equation for this term is appended to the matrix of circuit equations, as is described in a later section.

### I. C. Load Model

Real and imaginary load current (I_{RL} and I_{IL}, respectively) as a function of real and imaginary load voltage (V_{RL} and V_{IL}, respectively) can be derived by solving the following equations simultaneously:

P_{L}=V_{RL}I_{RL}+V_{IL}I_{IL} (10)

Q_{L}=−V_{RL}I_{IL}+V_{IL}I_{RL} (11)

The solution yields the following expressions:

$$\begin{matrix}{I}_{RL} = \frac{{P}_{L} {V}_{RL} + {Q}_{L} {V}_{IL}}{{V}_{RL}^{2} + {V}_{IL}^{2}} & ( 12 ) \\ {I}_{IL} = \frac{{P}_{L} {V}_{IL} - {Q}_{L} {V}_{RL}}{{V}_{RL}^{2} + {V}_{IL}^{2}} & ( 13 )\end{matrix}$$

Linearizing the load via Taylor expansion results in three elements in parallel in both circuits: a conductance, a voltage-controlled current source, and an independent current source. The values are given in Table I and the models in FIG. 4. G₃, I₇, and I₈ are the load elements in the real circuit, and G₆, I₁₅, and I₁₆ are the load elements in the imaginary circuit.

### I. D. Slack Bus Model

The slack bus is the simplest bus type to model. In the real circuit, it appears as an independent voltage source of value V_{REF} cos θ, and in the imaginary circuit it appears as a voltage source of value V_{REF} sin θ. When the phase θ is 0°, the imaginary component appears as a short to ground.

### I. E. Transmission Line Model

A transmission line is represented in the equivalent circuit as a pi-model as shown in FIG. 2B. Equation 10 can be used as a starting point for splitting this model into real and imaginary sub-circuits.

Ĩ=\tilde{Y}\tilde{V}=(Y_{R}+jY_{I})(V_{R}+jv_{I})=(Y_{R}V_{R}−Y_{I}V_{I})+j(Y_{I}V_{R}+Y_{R}V_{I}) (14)

The admittance of the shunt elements in the pi-model is purely imaginary

$$( {Y}_{shunt} = j \frac{B}{2} ) ,$$

but the admittance of the branch connecting them has both real and imaginary components

$$( {Y}_{branch} = \frac{1}{R + jX} = \frac{R}{{R}^{2} + {X}^{2}} - j \frac{X}{{R}^{2} + {X}^{2}} ) .$$

Plugging these expressions into Equation 14 yields:

$$\begin{matrix}{I}_{R , branch} = \frac{R}{{R}^{2} + {X}^{2}} {V}_{R , branch} + \frac{X}{{R}^{2} + {X}^{2}} {V}_{I , branch} & ( 15 ) \\ {I}_{I , branch} = \frac{R}{{R}^{2} + {X}^{2}} {V}_{R , branch} - \frac{X}{{R}^{2} + {X}^{2}} {V}_{I , branch} & ( 16 ) \\ {I}_{R , shunt} = - \frac{B}{2} {V}_{I , shunt} & ( 17 ) \\ {I}_{I , shunt} = \frac{B}{2} {V}_{R , shunt} & ( 18 )\end{matrix}$$

An element where the current through it is proportional to the voltage across it is represented as a conductance (G₁, G₂ in the real circuit; G₄, G₅ in the imaginary circuit). An element where the current through it is proportional to the voltage across its companion element in the opposite sub-circuit is represented as a voltage-controlled current source (I₅, I₆, in the real circuit, which are dependent on the voltages across I₁₃, I₁₄ in the imaginary circuit, and vice versa).

### I. F. Transformer Model

Although a transformer is not present in the simple 3-bus example of FIG. 2, they appear as branch elements connecting buses in nearly every network of reasonable size. To derive their split circuit equivalent model, the primary and secondary voltages (\tilde{V}₁ and \tilde{V}₂) are related through the turns ratio n and the phase angle θ (which is only non-zero for phase shifters):

$$\frac{{\tilde{V}}_{1}}{{\tilde{V}}_{2}} = {ne}^{j θ} \to \frac{{V}_{1 R} + {jV}_{1 I}}{{V}_{2 R} + {jV}_{2 I}} = n cos θ + jn sin θ \qquad ( 19 )$$

Solving for the real and imaginary components of V₂, results in the following expressions for secondary side elements:

$$\begin{matrix}{V}_{2 R} = \frac{{V}_{1 R} cos θ}{n} + \frac{{V}_{1 I} sin θ}{n} & ( 20 ) \\ {V}_{2 I} = \frac{{V}_{1 I} cos θ}{n} - \frac{{V}_{1 R} sin θ}{n} & ( 21 )\end{matrix}$$

The first term of Equation 20 represents a voltage-controlled voltage source, where the controlling voltage is the primary side voltage in the real circuit. The second term is a voltage-controlled voltage source, but here the controlling voltage is the primary side voltage in the imaginary circuit. The same types of elements are found in Equation 21.

Primary and secondary side currents (Ĩ₁ and Ĩ₂) can also be expressed in terms of the turns ratio:

$$\frac{{\tilde{I}}_{2}}{{\tilde{I}}_{1}} = - {ne}^{- j θ} \to \frac{{I}_{2 R} + {jI}_{2 I}}{{I}_{1 R} + {jI}_{1 I}} = - ( n cos θ - jn sin θ ) \qquad ( 22 )$$

From Equation 22 expressions for the primary side current can be derived:

$$\begin{matrix}{I}_{1 R} = - \frac{{I}_{2 R} cos θ}{n} + \frac{{I}_{2 I} sin θ}{n} & ( 23 ) \\ {I}_{1 I} = \frac{{I}_{2 I} cos θ}{n} - \frac{{I}_{2 R} sin θ}{n} & ( 24 )\end{matrix}$$

The first term of Equation 23 represents a current-controlled current source, where the controlling current is the current which flows through the secondary side in the real circuit. The second term represents a current-controlled current source, but here the controlling current is the current which flows through the secondary side in the imaginary circuit. The same types of elements are found in Equation 24.

The final term to model is the leakage impedance, Z_{TR}=R_{TR}+jX_{TR}. This is handled the same way as the branch impedance found in transmission lines. A similar analysis results in the following equations:

$${I}_{R , TR} = \frac{{R}_{TR}}{{R}_{TR}^{2} + {X}_{TR}^{2}} {V}_{R , TR} + \frac{{X}_{TR}}{{R}_{TR}^{2} + {X}_{TR}^{2}} {V}_{I , TR} \qquad ( 25 )$$

$${I}_{I , TR} = \frac{{R}_{TR}}{{R}_{TR}^{2} + {X}_{TR}^{2}} {V}_{R , TR} - \frac{{X}_{TR}}{{R}_{TR}^{2} + {X}_{TR}^{2}} {V}_{I , TR} \qquad ( 26 )$$

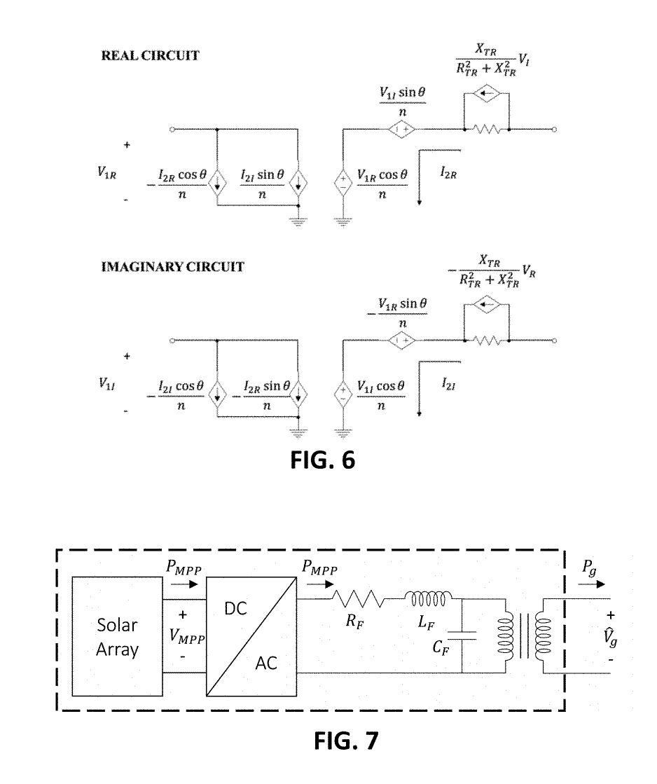

The first term of Equation 25 is a conductance and the second term is a voltage-controlled current source; likewise for Equation 26. A full equivalent circuit model for the transformer is shown in FIG. 6.

### I. G. Shunt Model

Shunt elements at buses can be modeled similarly to the transmission line shunts. This modeling can be developed using Equation 14, noting that Yₛₕ=Gₛₕ+jBₛₕ. Usually the shunts are purely susceptive. The following expressions are obtained:

I_{R,shunt}=GₛₕV_{R}−BₛₕV_{I} (27)

I_{I,shunt}=BₛₕV_{R}+GₛₕV_{I} (28)

The first term of Equation 27 represents a conductance to ground and the second term represents a controlled current source to ground, where the controlling voltage is the voltage across the conductance element in the imaginary circuit. Likewise, the first term of Equation 28 represents a conductance to ground and the second term represents a controlled current source to ground, where the controlling voltage is the voltage across the conductance element in the real circuit.

### I. H. Generalized Modeling

All electrical devices can be characterized by a relationship between current and voltage. A nonlinear expression for generator current in terms of voltage based on fixed power and voltage constraints is provided above. This approach can be extended to model any nonlinear relationship that describes an element of the power system, allowing for novel models that are not compatible with traditional power flow analyses. In this section, a model of a solar array is derived to illustrate how generalized modeling in terms of current and voltage can be used to create physical buses that cannot be described as constant-PV or constant-PQ.

I. H. i. Description of Solar Power System

FIG. 7 shows a block diagram of a grid-connected solar system. A DC-to-AC inverter applies a maximum power point tracking (MPPT) control strategy to force the solar array to operate at its maximum power point (P_{MPP}), with an output DC voltage of V_{MPP} and output DC current of I_{MPP}. The AC output of the inverter is filtered by an RLC circuit and an isolation transformer transfers the generated power (P_{g}) to the grid. It can be assumed that Q=0, since solar systems are commonly designed to operate at unity power factor and the real power output of the inverter is equal to the solar output (P_{MPP}); a different model can be derived for nonzero reactive power. In order to solve for power flows, voltages and currents of the circuit in FIG. 7, the entire system can be solved together without treating the bus as fixed-PV or fixed-PQ.

I. H. ii. Equivalent Circuit Representation

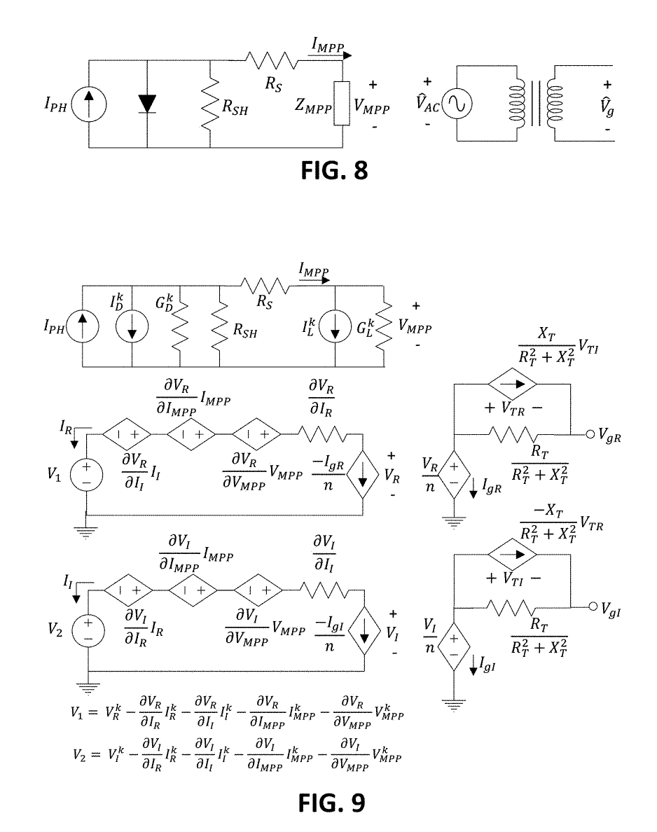

An equivalent circuit of the system diagram in FIG. 7 is shown in FIG. 8. The solar array is replaced by a single diode model, where I_{PH} is the photovoltaic current generated by solar irradiance, R_{SH} is a parasitic shunt resistance, and R_{S} is the series resistance of the array. The inverter loads the array with impedance Z_{MPP} to force the array to operate at its maximum power point, which occurs when:

$$\frac{\partial ( {I}_{MPP} {V}_{MPP} )}{\partial {V}_{MPP}} = {I}_{MPP} + {V}_{MPP} \frac{\partial {I}_{MPP}}{\partial {V}_{MPP}} = 0 \qquad ( 29 )$$

The AC side represents the output of the inverter. \hat{V}_{AC} is the voltage that appears at the input to the transformer and is equal to the output voltage of the inverter minus any voltage drop across the filter elements. The output voltage of the transformer \hat{V}_{g} is applied directly to the grid. The real output power P_{g} is equal to the generated solar power P_{MPP} minus any real power losses in the filter and transformer.

I. H. iii. Linearized Split Circuit Model

To solve the circuit in FIG. 8, it must be linearized following the same procedures outlined above. The current through the diode (I_{D}) is given by:

I_{D}=I₀(e^{V}^{^{D}}^{/a}−1) (30)

where I₀ is the reverse saturation current, V_{D} is the diode voltage, and a is non-ideality factor. This equation is linearized by taking a first-order Taylor expansion to yield:

$${I}_{D}^{k + 1} = {I}_{D}^{k} + \frac{\partial {I}_{D}}{\partial {V}_{D}} {\vert}_{{V}_{D}^{k}} {V}_{D}^{k + 1} - \frac{\partial {I}_{D}}{\partial {V}_{D}} {\vert}_{{V}_{D}^{k}} {V}_{D}^{k} \qquad ( 31 )$$

The first and third terms depend only on values from the previous iteration and can therefore be represented as an independent current source. The second term gives a component of the diode current that is proportional to the diode voltage and therefore represents a conductance. The parallel combination of these elements replaces the diode in the linearized circuit of FIG. 9.

The load the inverter presents to the solar array forces maximum power operation when Equation 29 holds. By evaluating the equation at the maximum power point, it can be seen that the current I_{MPP} flowing through the load is:

$${I}_{MPP} = {V}_{MPP} \frac{( {I}_{0} {R}_{SH} χ - a )}{a ( {R}_{SH} + {R}_{S} ) + {I}_{0} {R}_{S} {R}_{SH} χ} \qquad ( 32 )$$

where χ=exp([V_{MPP}+I_{MPP}R_{S}]/a). By taking a Taylor expansion of Equation 32, two equivalent circuit elements can be obtained: an independent current source (I_{L}^{k}) and a conductance (G_{L}^{k}). These are shown at the output of the DC circuit in FIG. 9.

The AC side of the circuit must be split into real and imaginary parts. It was assumed that the reactive power is zero and that the real output power of the inverter is P_{MPP}. Using the relationship expressed in Equation 1, it is possible to solve for the real and imaginary voltage components of \hat{V}_{AC} to obtain:

$$\begin{matrix}{V}_{R} = \frac{{I}_{R} ( {I}_{MPP} {V}_{MPP} )}{{I}_{R}^{2} + {I}_{I}^{2}} - {R}_{F} {I}_{R} & ( 33 ) \\ {V}_{I} = \frac{{I}_{I} ( {I}_{MPP} {V}_{MPP} )}{{I}_{R}^{2} + {I}_{I}^{2}} - {R}_{F} {I}_{I} & ( 34 )\end{matrix}$$

Note that the voltage drop across the filter resistance was lumped into the source values. By taking Taylor expansions of Equations 33 and 34, it is possible to obtain the equivalent circuit components shown in FIG. 9. The real circuit contains an independent voltage source, two current-controlled voltage sources (one dependent on I_{I} and the other on I_{MPP}), and one voltage-controlled voltage source (dependent on V_{MPP}). Similar elements are shown for the imaginary circuit. The procedure for splitting a transformer is provided above.

### II. Tree-Link Analysis and Formulation of Equations

The previous section details the conversion of the electrical power system to an equivalent circuit representation. The governing equations of this equivalent circuit can be formulated in terms of voltage and current conservation equations. For example, nodal equations can be written to express Kirchoff's current law (KCL) at each node, and the resulting system can be solved to obtain the voltage at every circuit node. This “nodal analysis” technique (and modified techniques derived from it) is commonly used in circuit simulation software to formulate circuit equations. However, it is not possible to model perfect switches with this technique, which are important in contingency analyses of electrical power systems, and the matrix representing the system of equations does not have optimal conditioning.

A graph theory-based method known as tree-link analysis (TLA) can be used to solve the circuit for voltages and currents in the embodiment described herein. A directed graph of the circuit can be constructed, and a spanning tree can be found that touches all nodes and forms no loops. Branches not included in the tree form a set of links, or co-tree. A system of voltage and current conservation equations can be formulated such that the solutions are the tree branch voltages and the link currents. Inclusion of an element in the tree can be based on priority ordering, with greatest preference given to voltage sources, capacitors, and small-valued resistors, for which solving for the voltage is most efficient. Current sources, inductors, and large resistors are included in the links, as it is more efficient to solve for their currents. The TLA formulation yields provably optimal matrix conditioning.

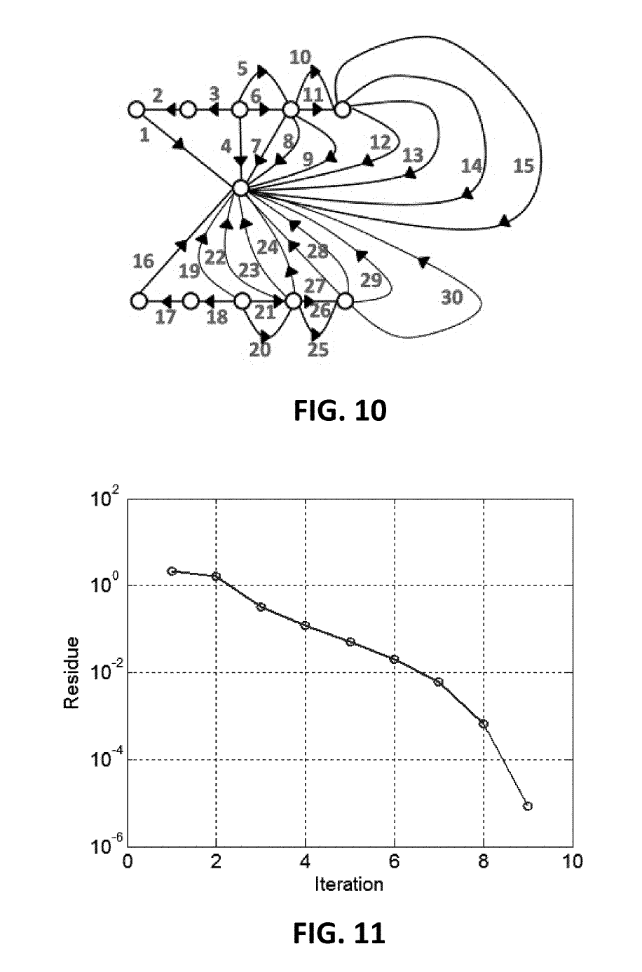

FIG. 10 shows the graph representation of the three-bus split circuit, where each node of the graph represents a node in the circuit and each branch represents a two-terminal element in the circuit. The direction given to each branch represents the current flow through the element and is based on the associated reference direction of that element; for example, the current through a voltage source is defined as positive when directed from the positive to the negative terminal of the source. An incidence matrix (A) of size (#nodes×#branches) can be used to represent the graph, such that: A(i,j)=1 if branch j is directed away from node i, A(i,j)=−1 if branch j is directed to node i, and A(i,j)=0 if branch j does not touch node i.

After the elements are ordered into a tree and co-tree, A can be row-reduced to form the cutset matrix F, where each row of F represents a fundamental cutset. The tree branch currents (iₜ) can be expressed in terms of the link currents (i₁) via F (a statement of Kirchhoff's current law (KCL)):

iₜ=−Fi_{I} (35)

To determine the tree branch voltages and link currents the TLA system of equations is solved:

$$\begin{matrix}[ \begin{matrix}1 + α {F}^{T} & RF \\ - {GF}^{T} & 1 + β F\end{matrix} ] [ \begin{matrix}{v}_{t} \\ {i}_{l}\end{matrix} ] = [ \begin{matrix}{V}_{t} \\ {I}_{l}\end{matrix} ] \\ where \text{:} & ( 36 ) \\ {v}_{t} = {Ri}_{t} + {V}_{t} + α {v}_{l} & ( 37 ) \\ {i}_{l} = {Gv}_{l} + {I}_{l} + β {i}_{t} & ( 38 )\end{matrix}$$

R is a matrix of resistances used to calculate the voltage across a tree branch from the current flowing through the branch; it is a statement of Ohm's law. Vₜ is a vector of independent voltage sources that appear on tree branches. α is a matrix where the only non-zero entries represent dependent voltage sources in the tree that are controlled by link voltages. G, I_{I}, and β have similar meanings; in this case, G is a matrix of conductances, I₁ a vector of independent current sources, and β a matrix of tree branch current-controlled current sources that appear in the co-tree. Tree branch currents and link voltages can be calculated from the tree branch voltages and link currents.

For some applications the TLA system of voltage and current conservation equations must be appended by additional equations; for example, the voltage magnitude constraint equations must be appended to the system when the current source-based generator model is being used, as described above. In that example, generator reactive power Q_{g} is also added as a variable, leading to the following system of equations:

$$[ \begin{matrix}1 - α {F}^{T} & RF & 0 \\ - {GF}^{T} & 1 + β F & τ \\ γ & 0 & 0\end{matrix} ] [ \begin{matrix}{v}_{t} \\ {i}_{l} \\ {Q}_{g}\end{matrix} ] = [ \begin{matrix}{V}_{t} \\ {I}_{l} \\ {γ}_{G}\end{matrix} ] \qquad ( 39 )$$

τ represents the partial derivatives of the generator current (real and imaginary) with respect to Q_{g}, and γ and γ_{G} represents the linearized constraints derived from Equation 2 to keep the voltage magnitude of a given generator at its prescribed value. The other terms are the standard TLA circuit equations.

### III. Results and Discussion

In one experiment, a prototype solver was implemented in MATLAB™ software, available from Mathworks, Inc., Natick, Mass., although other computing and/or simulation software could readily be used by one of ordinary skill in the electrical power planning, simulation, generation, transmission, and/or distribution arts, among others, to implement one or more of the methods disclosed herein without undue experimentation after reading this disclosure in its entirety. The program developed reads in power flow case files in the standard IEEE CDF format, although any other suitable format could be used, and replaces each bus, line, transformer, and any other electrical power system component with their equivalent circuit models from Section I. A graph and spanning tree are built from this circuit and the TLA equations are formulated. These equations are solved on every NR iteration (see FIG. 3). If the result of an iteration would yield an infeasible solution on the next iteration (e.g., a complex number for a tree branch voltage in the real circuit, which can occur if the discriminant of Equation 3 or Equation 4 becomes negative), no values are updated and the iteration is repeated with damping. The sign of the change in value remains the same, but the magnitude of the change is reduced. If the solution is acceptable, the last remaining step is to calculate the reactive power of the generator buses and the voltage magnitude and phase of the load buses. This is trivial, because the solution of the tree/link equations of the split circuit yields all values for real and imaginary voltages and currents at every bus.

The proposed implementation successfully simulated the 14-, 30-, 57-, 118-, and 300-bus IEEE test cases. Iteration counts are given in Table II. The large number of iterations required, especially for the bigger test systems, is a direct result of damping, because very small steps were taken to avoid non-physical solutions.

TABLE II
ITERATION COUNT FOR IEEE STANDARD TEST CASES.

| Case | Iteration Count |
|---|---|
| 14-bus | 29 |
| 30-bus | 30 |
| 57-bus | 30 |
| 118-bus | 98 |
| 300-bus | 265 |

The voltage source-based generator model that requires damping leads to excessive iteration counts for arbitrary initial guesses, as discussed above. However, the current source based generator model introduced above does not require damping and requires significantly fewer iterations. Table III shows that only 5-7 iterations are required to converge on a solution independent of system size for the test systems ranging from a few buses to several thousand buses. An arbitrary initial guess was used; a good initial guess would further reduce the iteration count. This is a large improvement over the voltage source model introduced earlier in this disclosure, where the number of iterations increased with system size to the point where it was practically unfeasible to run cases with more than a few hundred buses.

TABLE III
ITERATION COUNTS FOR TEST SYSTEMS USING
VOLTAGE SOURCE-BASED (VS) AND CURRENT
SOURCE-BASED (CS) GENERATOR MODELS

| | #Buses | | | | | | |
|---|---|---|---|---|---|---|---|
| | 14 | 30 | 57 | 118 | 300 | 2383 | 3120 |
| VS Model | 29 | 30 | 30 | 98 | 265 | — | — |
| CS Model | 5 | 5 | 5 | 5 | 6 | 7 | 7 |

Beyond the lack of damping, the proposed current source generator model may provide faster convergence because it expresses the generator in terms of the more “natural” variable. A typical solution in a power system is one where the load voltages are high (≈1 p.u. for a base of nominal grid voltage) and the currents are correspondingly low to satisfy S=VI*, where S is given. The generators, of course, supply the current to the system. For these high voltage/low current solutions, the generator is therefore better suited as a link element in the TLA formulation. Being able to model a bus in either a current or voltage representation, and to choose the best variable to solve for further illustrates the flexibility of this method; in traditional power flow, the generator, or load models do not have this flexibility.

An ill-conditioned 11-bus system was also tested. The solution converged in nine iterations from a flat start with all load voltages initially set to 1+j0. The NR residue at each iteration for this test case is shown in FIG. 11.

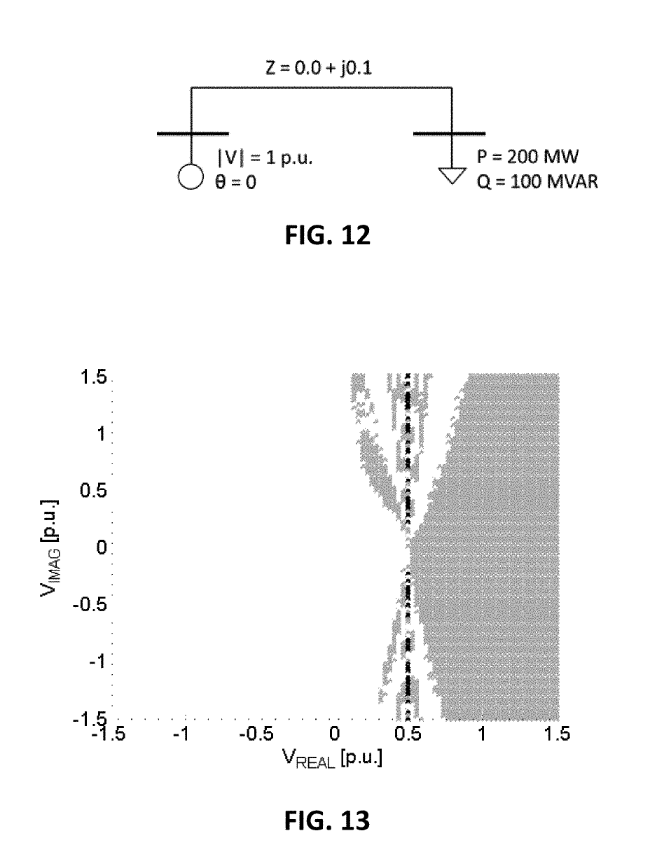

Traditional power flow methods are known to be sensitive to the choice of the initial guess (or seed) of the solution. Consider the simple two-bus system in FIG. 12 with a slack bus and a load. The system has two solutions for the load voltage, one high (stable) and one low (unstable). An initial guess of the load voltage (including both real and imaginary components) is required to run a power flow simulation. This guess can be represented as a point on a complex plane, with the y-axis representing the imaginary component of the voltage and the x-axis representing the real component. Ten thousand choices of initial guesses were supplied to MATPOWER (a package for use with MATLAB™ software for simulating and solving power flow and optimal power flow problems), of which 6785 led to convergence to the low voltage solution (white region in FIG. 13), 49 led to non-convergence in 1000 iterations (black points in FIG. 13), and the remaining 3166 led to the stable high voltage solution (shown in gray in FIG. 13).

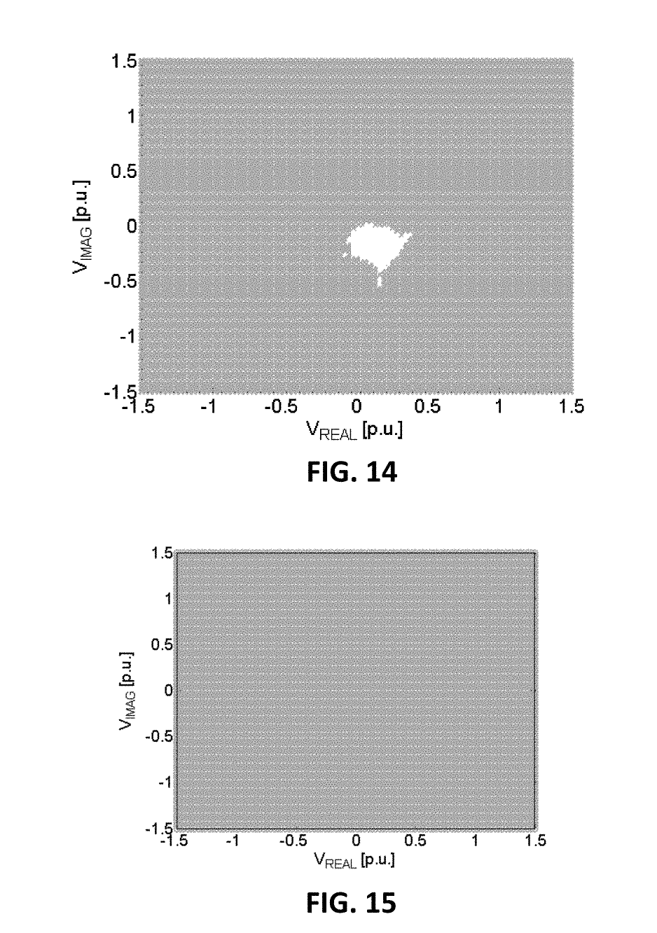

The same experiment was run using the current-voltage TLA simulator developed by the present Inventors. FIG. 14 shows that this method is significantly less sensitive to the initial guess than traditional power flow, with only 131 out of the 10000 seeds leading to convergence to the unstable low voltage solution. However, the equivalent circuit formulation allows for borrowing techniques from circuit simulators to further improve the convergence properties. A common method to find the DC solution to a non-linear circuit is power stepping, where the supply voltage (VDD) is scaled down and stepped back up to its original value in increments. This technique is similar to representing “turning on the circuit” in simulation and can equally be applied to “turning on the grid.” All generation and loads were scaled back by a factor of 0.001. The solution to this scaled system was then used as the initial guess for the next iteration where the loads are increased, and this was repeated until all loads are returned to their initial values. FIG. 15 shows that any choice of initial guess leads to convergence to the correct solution when this approach is applied. This is because unstable solutions only occur when the current is large enough such that a small voltage magnitude can still yield the constant P and Q demanded by the load. When P and Q are scaled down as they were here, low values for the current were found even for low voltage initial guesses. This allowed the simulation to avoid being steered toward high current solutions that lead to low bus voltages.

The same experiment was tried on a number of IEEE test systems, with all loads assumed to begin with the same voltage magnitude and angle. Fewer than 20 of the ten thousand initial guesses caused convergence to an unstable low-voltage solution in each case without power stepping. When power stepping is applied, 100% of initial guesses led to the correct solution.

It is worth noting that this technique does nothing to improve the convergence properties of traditional power flow methods. This is because scaling P and Q does not affect the Jacobian, nor does it help force the current to be small (due to the lack of a current variable). Applying this technique to traditional power flow results in a plot similar to FIG. 13. The only difference is that every initial guess converges to one of the two solutions, but nearly 70% of those initial guesses cause convergence to the low voltage solution.

To demonstrate the use of the generalized solar bus model, a generator was removed from the IEEE 14-bus system and replaced with the equivalent model of FIG. 7. The solar array was designed to output 40 MW, the same real power that was delivered by the generator it replaced. The AC voltages and currents of the model were scaled to their per unit values to be compatible with the rest of the system, but the DC circuit was solved with standard units.

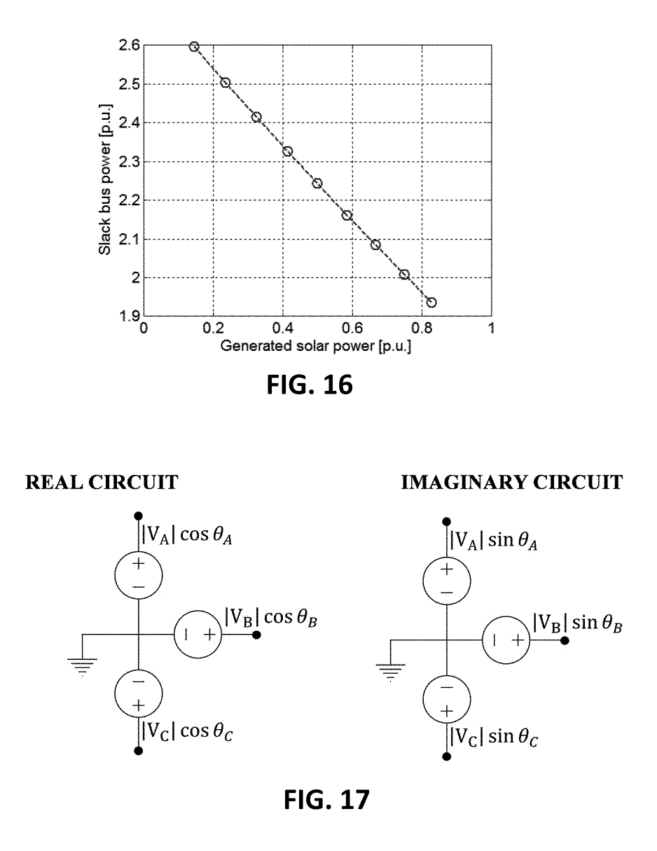

The generalized circuit-based modeling allows the DC and AC circuits to be solved together with the same algorithm and without having to fit the model to a PQ- or PV-bus type. As the DC circuit converges to the maximum power point, the AC side transfers that power output to the rest of the grid. Convergence is obtained in seven iterations with no damping and an absolute tolerance of 1e-4 p.u. The solar array and slack bus are the only sources of real power in the system, and the output power of the latter decreases with increasing solar power injected into the network, as shown in FIG. 16.

### III. A. Circuit Simulation Techniques

While the I-V formulation disclosed herein has demonstrated superior convergence properties over conventional polar coordinate based formulation for three-phase power flow, the present inventors have observed convergence issues with systems containing PV buses. This section demonstrates how circuit simulation techniques can provide robust convergence for any complex I-V formulation that is derived from the split equivalent circuit representation disclosed herein. Application to power grid test systems with up to 10⁴ buses demonstrates consistent global convergence to the correct physical solution from arbitrary initial conditions.

III. A. i. Variable Limiting

The solution space of the system node voltages in a power flow problem is well defined. While solving the power flow problem, a large NR step may step out of this solution space and result in either non-convergence or convergence to non-physical or unstable solution. It is important, therefore, to limit the NR step before it makes an invalid step out of the solution space. Variable limiting can be applied to achieve the postulated goal. In this technique, the state variables that are most sensitive to initial guesses are damped when the NR algorithm takes a large step out of the predefined solution space. Note that not all of the variables are damped, and circuit simulation research has shown that variable limiting has provided superior convergence as compared to damped NR in general.

In a power flow problem, the voltages on the PV node are highly sensitive to the reactive power (Q) value at that node. In an I-V formulation of a power flow problem in accordance with the present disclosure, each PV node augments the solution space by an additional unknown variable, Q, for which an initial guess has to be assigned. However, unlike the node voltages, it is very hard to choose the appropriate initial guess for these Q variables as they exhibit a large solution space. Therefore, with an arbitrary choice of initial value, the power flow problem may diverge or converge to the wrong or undesired solution.

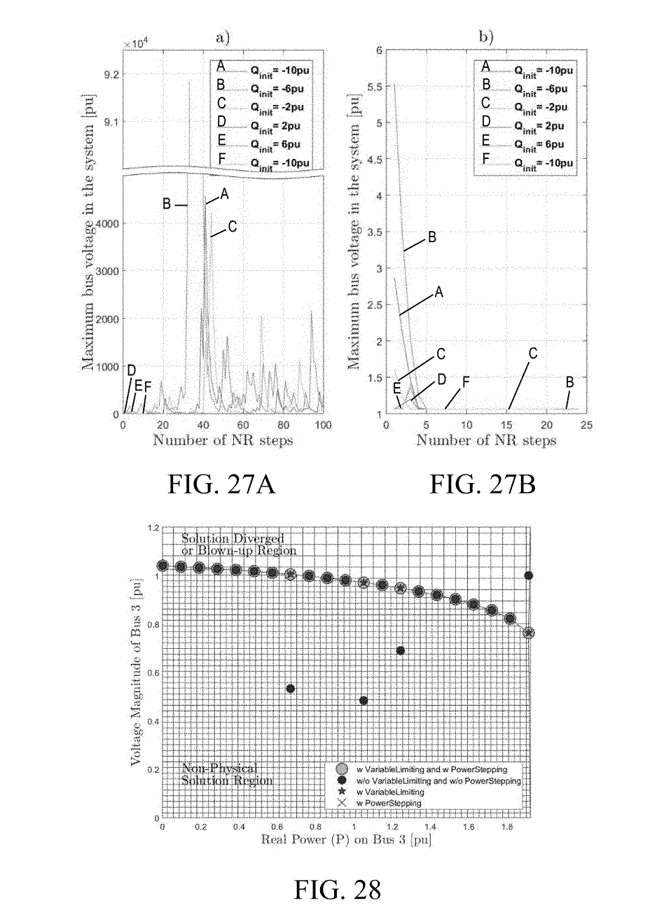

In order to tackle this problem, in some embodiments the voltages at the PV node are damped during the NR iterations whenever they make a large step out of the pre-defined solution space. FIGS. 27A and 27B (FIG. 5) can be used to demonstrate this graphically. The plots in FIGS. 27A and 27B show results for a 2383 bus test system that was represented in I-V formulation in accordance with the present disclosure, and simulations were run on it for six different initial guesses for unspecified Q. The maximum bus voltage from the solution of the power flow problem for each initial guess was then plotted for two scenarios: without and with variable limiting enabled. The plots in FIGS. 27A and 27B show that when variable limiting is not enabled, the voltage solution diverges to very high magnitudes (up to 10⁴) and may not converge even in 100 iterations. However, when variable limiting is enabled, divergence is not observed and the bounded bus voltages result in fast convergence.

In order to apply variable limiting in a prototype simulator developed by the present inventors, the mathematical expressions, discussed above, for the PV nodes in the system are modified as follows:

$${{{I}_{CG}^{k + 1} = α \frac{\partial {I}_{CG}}{\partial {V}_{RG}} \vert}_{{Q}_{G}^{k} , {{V}_{RG}^{k}}_{,} {V}_{IG}^{k}} ( {V}_{RG}^{k + 1} - {V}_{RG}^{k} ) + {I}_{CG}^{k} + α \frac{\partial {I}_{CG}}{\partial {V}_{IG}} \vert}_{{Q}_{G}^{k} , {V}_{RG}^{k} , {V}_{IG}^{k}} ( {V}_{IG}^{k + 1} - {V}_{IG}^{k} ) + {\frac{\partial {I}_{CG}}{\partial {Q}_{G}} \vert}_{{Q}_{G}^{k} , {V}_{RG}^{k} , {V}_{IG}^{k}} ( {Q}_{G}^{k + 1} - {Q}_{G}^{k} ) \qquad ( 40 )$$

wherein, 0≦α≦1 and Cε{R, I} represents the placeholder for real and imaginary parts. The magnitude of a is dynamically varied through heuristics such that convergence to correct physical solution is achieved in the most efficient manner.
III. A. ii. Dynamic Power Stepping

As with large circuit simulation problems, variable limiting alone can be insufficient for solving some of the most complex large-scale power flow problems. Variable limiting alone fails for cases where the Jacobian matrix is close to being singular or when the solution matrix remains out of the expected bounds of the solution space over multiple iterations. For such cases, we find it necessary to apply a continuation method, such as power stepping, which is analogous to the source stepping and gₘᵢₙ stepping approaches in standard circuit simulation solvers.

The aforementioned power stepping technique corresponds to a continuation method approach wherein at first the power corresponding to respective loads and generators in the system are scaled back by a factor of β. In addition, the voltage equality constraint corresponding to the PV bus can also be concurrently scaled down by the same factor β. If the power and voltage set points corresponding to these loads and generators are scaled down all the way to zero, then the system solution becomes trivial. In the case where the voltage equality constraint is not scaled down, the current source non-linearities of the PV and PQ buses are eliminated and the voltage equality remains as the only non-linearity for the PV buses. Therefore, by applying the power stepping factor β, the non-linearities in the system are greatly eased and convergence is easily achieved. Upon convergence, the factor is gradually scaled back up to unity in order to solve the original problem. In this method, as in all continuation methods, the solution from the prior step is used as the initial condition for the next step:

∀iεPV:Pᵢ=βPᵢ (40)

∀iεPQ:Pᵢ=βPᵢΛQᵢ=βQᵢ (41)

∀iεβ(|Vᵢ^{set}|²−Vᵢ^{I}^{²})−Vᵢ^{R}^{²} (42)

wherein, PQ are all PQ buses and PV are all PV buses and Vᵢ^{set} is the set voltage magnitude for the given PV bus.

It is worth noting that this technique does not improve the convergence properties of traditional ‘PQV’ power flow formulation. This is because scaling P and Q does not affect the Jacobian.

III. A. iii. Tx Stepping

It is worth noting that due to the non-linear formulation of the power flow problem, the solution to the problem may result in high or low system voltages. The low voltage solutions are meaningless for the actual power grid analyses and should be avoided. To do so, a new homotopy method is introduced that is specifically targeted for power flow systems: “Tx Stepping.” In Tx (transmission line) Stepping, the transmission line and transformer models are modified to first solve the initial problem with a formulation that corresponds to a trivial solution. Specifically, a large value conductance (G) and susceptance (B) are added in parallel to each transmission line and transformer model in the system and the transformer taps (tr) are all set to 1 pu. Importantly, the solution to this initial problem results in high system voltages as they are essentially driven via the slack bus voltage and the PV bus voltages due to the low voltage drops in the lines and transformers (due to the added conductances and susceptances). Subsequently, like other continuation methods, the formulated system problem is then gradually stepped back to representing the original system by taking small increment steps of the homotopy factor (t) until convergence for the original problem is achieved. Mathematically, this is expressed as:

∀iε{Tx,Xfmrs}:Gᵢ=Gᵢ+tγGᵢ (43)

∀iε{Tx,Xfmrs}:Bᵢ=Bᵢ+tγBᵢ (44)

∀iεXfmrs:tr=tr+t(1−tr) (45)

wherein, Xfmrs is a set of all transformers in the system and Tx is the set of all the transmission lines in the system. γ is the scaling factor for the Gs and Bs and homotopy factor t represents the modified system for the value of 1 and represents the original system for the value of 0. During this method, the homotopy factor t is gradually modified from the value of 1 to 0.

Along with ensuring convergence to a stable solution, Tx stepping can be used to further avoid the unwanted low voltage solutions since the initial problem results in a solution with high system voltages, and each subsequent step of the homotopy approach deviates only slightly from this initial solution, thereby guaranteeing convergence to the high voltage solution for the original problem.

### III. A. iv Exemplary Results

In this section, exemplary cases are described in which a prototype solver (SUGAR (Simulation with Unified Grid Analyses and Renewables)) was used to validate the superior performance offered by the equivalent circuit formulation approach disclosed herein. The exemplary cases affirm that the proposed framework can guarantee convergence to the correct physical solution for all power flow cases, independent of the choice of initial guess.

In the first example, simulations were run for the IEEE 14 bus test system (from flat start) in steps of increasing loading factors (up to 4×) for the following four scenarios: 1) both power stepping and variable limiting disabled; 2) with power stepping enabled and variable limiting disabled; 3) with variable limiting enabled and power stepping disabled; and 4) both power stepping and variable limiting enabled. The solution of the bus 3 voltage magnitude is then captured at the end of each simulation and the results are plotted in the FIG. 28. The plot in FIG. 28 shows that convergence to the correct physical solution is achieved for each simulation instance when either variable limiting or power stepping is enabled. However, without these techniques enabled in SUGAR, the solution in many simulation instances either converges to the wrong solution or diverges altogether.

It is important to note that the use of power stepping or variable limiting alone may not guarantee convergence to the correct physical solution as the complexity and the size of the system increases. This is demonstrated in a second example wherein power flow simulations are run on large 2869 and 9241 bus test systems.

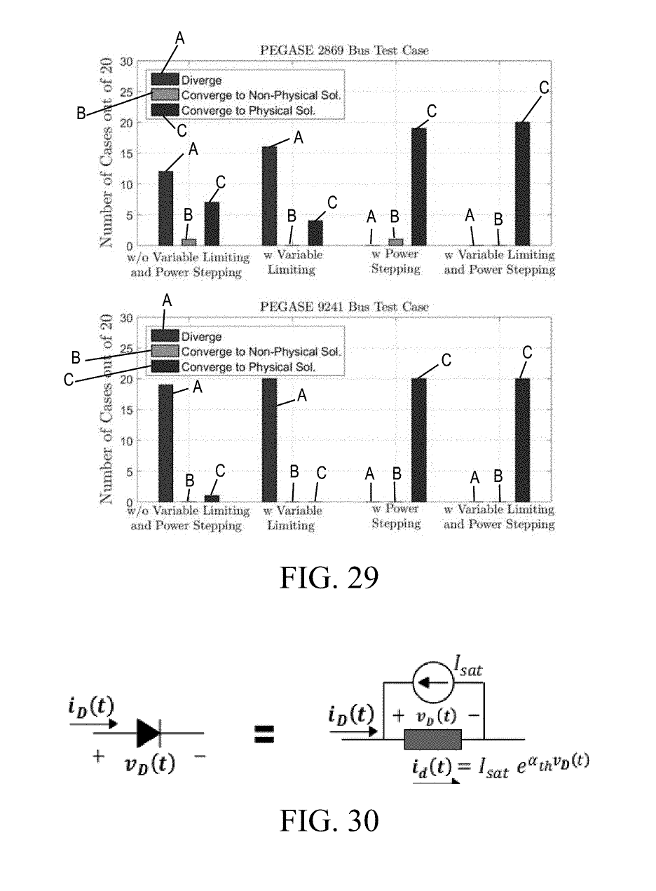

In this second example, power flow simulations are run on both the 2869 and 9241 bus test systems for 20 different initial guesses for Q values that are uniformly distributed in the range of −10 p.u. and 10 p.u. All 20 simulations are run for each of these solver settings under the same four scenarios. The convergence results plotted in FIG. 29 show that without circuit simulation techniques, most of the cases in these systems either diverge or converge to the wrong, i.e. undesired solution. Convergence to the desired (functional controlled system) physical solution is only observed when both variable limiting and power stepping are enabled. In general, the two techniques discussed herein are by no means an exhaustive list of circuit simulation techniques that can be applied to the power flow problem or the three-phase power flow problem. Other circuit simulation techniques can also be incorporated into the equivalent circuit framework for even more robust and efficient simulations.

### IV. An Equivalent Circuit Formulation for Three-Phase Power Flow Analysis

A method of solving single phase power flow was presented above. In modeling real distribution systems it is generally not accurate to assume balanced operation, necessitating the modeling and interaction of all three phases of the power system. Here an extension of the aforementioned approach to handle unbalanced three phase power flow without loss of generality is described.

### IV. A. Slack Bus Model

In distribution system analysis, the transmission grid is usually modeled as a generator connected to a substation that feeds power into the distribution system and keeping the voltage at the substation constant. This generator or slack bus is the simplest bus type to model. Depending on the configuration to which it is connected, in the real circuit (real portion of the split circuit, as described above), it appears as an independent voltage source of value |V_{A}| cos θ_{A}, and in the imaginary circuit (imaginary portion of the split circuit, as described above) it appears as a voltage source of value |V_{A}| sin θ_{A}. It should be noted that if the slack bus is connected in a Wye configuration, its magnitude |V_{A}| represents the line-to-neutral voltage, while, if it is connected as a delta configuration, its magnitude |V_{A}| will represent the line-to-line voltage. The complete split circuit model for a 3-phase slack bus connected as a grounded Wye configuration is shown in FIG. 17.

### IV. B. Transmission Line Model

There are two possible ways of modeling the transmission line. The first approach is based on Kron reduction, which eliminates the neutral line from the model. The other approach involves considering all four lines without any reduction. Taking the former approach, after performing Kron reduction, the transmission line branch currents are governed by Ohm's Law, where \tilde{V}_{Aa}, \tilde{V}_{Bb} and \tilde{V}_{Cc}, are the voltage drops across the lines:

$$[ \begin{matrix}{\tilde{I}}_{A} \\ {\tilde{I}}_{B} \\ {\tilde{I}}_{C}\end{matrix} ] = [ \begin{matrix}{\tilde{Y}}_{aa} & {\tilde{Y}}_{ab} & {\tilde{Y}}_{a c} \\ {\tilde{Y}}_{ba} & {\tilde{Y}}_{bb} & {\tilde{Y}}_{bc} \\ {\tilde{Y}}_{ca} & {\tilde{Y}}_{cb} & {\tilde{Y}}_{cc}\end{matrix} ] [ \begin{matrix}{\tilde{V}}_{Aa} \\ {\tilde{V}}_{Bb} \\ {\tilde{V}}_{Cc}\end{matrix} ] \qquad ( 46 )$$

Since the admittances of the branches have both real and imaginary components

$$( {Y}_{ij} = \frac{1}{{R}_{ij} + {jX}_{ij}} = \frac{{R}_{ij}}{{R}_{ij}^{2} + {X}_{ij}^{2}} - j \frac{{X}_{ij}}{{R}_{ij}^{2} + {X}_{ij}^{2}} = {G}_{ij}^{s} + {jB}_{ij}^{s} ) ,$$

the system from Equation 47 can be split as:

$$[ \begin{matrix}{I}_{A}^{R} \\ {I}_{A}^{I} \\ {I}_{B}^{R} \\ {I}_{B}^{I} \\ {I}_{C}^{R} \\ {I}_{C}^{I}\end{matrix} ] = [ \begin{matrix}{G}_{aa}^{s} & - {B}_{aa}^{s} & {G}_{ab}^{s} & - {B}_{ab}^{s} & {G}_{a c}^{s} & - {B}_{a c}^{s} \\ {B}_{aa}^{s} & {G}_{aa}^{s} & {B}_{ab}^{s} & {G}_{ab}^{s} & {B}_{a c}^{s} & {G}_{a c}^{s} \\ {G}_{ba}^{s} & - {B}_{ba}^{s} & {G}_{bb}^{s} & - {B}_{bb}^{s} & {G}_{b c}^{s} & - {B}_{bc}^{s} \\ {B}_{ba}^{s} & {G}_{ba}^{s} & {B}_{bb}^{s} & {G}_{bb}^{s} & {B}_{bc}^{s} & {G}_{bc}^{s} \\ {G}_{ca}^{s} & - {B}_{ca}^{s} & {G}_{cb}^{s} & - {B}_{cb}^{s} & {G}_{cc}^{s} & - {B}_{cc}^{s} \\ {B}_{ca}^{s} & {G}_{ca}^{s} & {B}_{cb}^{s} & {G}_{cb}^{s} & {B}_{cc}^{s} & {G}_{cc}^{s}\end{matrix} ] [ \begin{matrix}{V}_{Aa}^{R} \\ {V}_{Aa}^{I} \\ {V}_{Bb}^{R} \\ {V}_{Bb}^{I} \\ {V}_{Cc}^{R} \\ {V}_{Cc}^{I}\end{matrix} ] \qquad ( 48 )$$

where the “R” and “I” superscripts denote the real and imaginary parts, respectively.

Using the same approach, the transmission line shunt current can be written in the same way, where \tilde{V}_{A}, \tilde{V}_{B} and \tilde{V}_{C} are the line-to-neutral node voltages. Since the admittance of the shunt elements in the pi-model is purely imaginary

$$( {\tilde{Y}}_{ij}^{sh} = j \frac{{B}_{ij}}{2} = {jB}_{ij}^{sh} ) ,$$

the following formulation is derived from Ohm's law:

$$[ \begin{matrix}{I}_{Ash}^{R} \\ {I}_{Ash}^{I} \\ {I}_{Bsh}^{R} \\ {I}_{Bsh}^{I} \\ {I}_{Csh}^{R} \\ {I}_{Csh}^{I}\end{matrix} ] = [ \begin{matrix}0 & - {B}_{aa}^{sh} & 0 & - {B}_{ab}^{sh} & 0 & - {B}_{a c}^{sh} \\ {B}_{aa}^{sh} & 0 & {B}_{ab}^{sh} & 0 & {B}_{a c}^{sh} & 0 \\ 0 & - {B}_{ba}^{sh} & 0 & - {B}_{bb}^{sh} & 0 & - {B}_{bc}^{sh} \\ {B}_{ba}^{sh} & 0 & {B}_{bb}^{sh} & 0 & {B}_{bc}^{sh} & 0 \\ 0 & - {B}_{ca}^{sh} & 0 & - {B}_{cb}^{sh} & 0 & - {B}_{cc}^{sh} \\ {B}_{ca}^{sh} & 0 & {B}_{cb}^{sh} & 0 & {B}_{cc}^{sh} & 0\end{matrix} ] [ \begin{matrix}{V}_{A}^{R} \\ {V}_{A}^{I} \\ {V}_{B}^{R} \\ {V}_{B}^{I} \\ {V}_{C}^{R} \\ {V}_{C}^{I}\end{matrix} ] \qquad ( 47 )$$

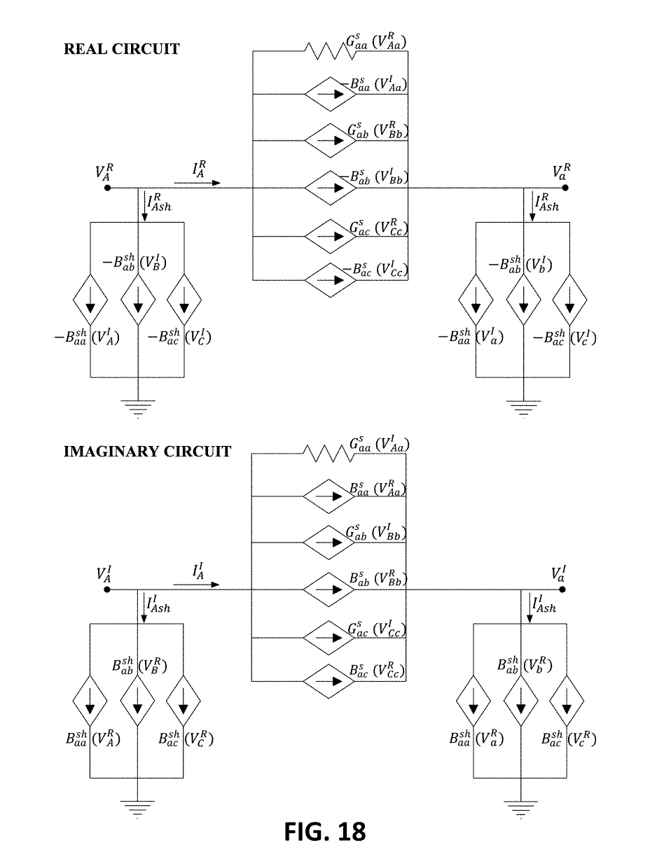

Equations 48 and 49 model the transmission line by using linear resistors and voltage-controlled current sources. FIG. 18 further shows an exemplary proposed split circuit model, including both real and imaginary sub-circuits, for one of the three phases of a transmission line.

As noted above, an alternative approach for transmission line modeling is to consider all four lines without Kron reduction. A similar split circuit model can be derived following the aforementioned steps where the neutral line is modeled as:

\tilde{V}_{N}=\tilde{Z}_{NA}Ĩ_{A}+\tilde{Z}_{NB}Ĩ_{B}+\tilde{Z}_{NC}Ĩ_{C}+\tilde{Z}_{N}Ĩ_{N} (50)

Each impedance term has both real and imaginary parts, i.e., (Zᵢⱼ=Rᵢⱼ+jXᵢⱼ). Substituting Zᵢⱼ into Equation 50 yields:

V_{N}^{R}=R_{N}I_{N}^{R}−X_{N}I_{N}^{I}+R_{NA}I_{A}^{R}−X_{NA}I_{A}^{I}+R_{NB}I_{B}^{R}−X_{NB}I_{B}^{I}+R_{NC}I_{C}^{R}−X_{NC}I_{C}^{I} (51)

V_{N}^{I}=R_{N}I_{N}^{I}+X_{N}I_{N}^{R}+R_{NA}I_{A}^{R}+X_{NA}I_{A}^{I}+R_{NB}I_{B}^{R}+X_{NB}I_{B}^{I}+R_{NC}I_{C}^{R}+X_{NC}I_{C}^{I} (52)

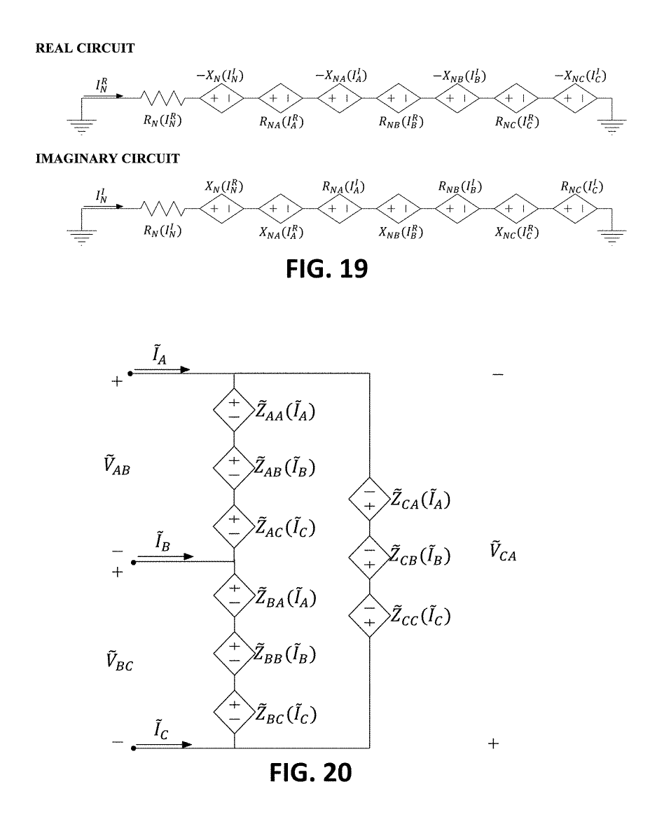

The complete split circuit model of a neutral line is shown in FIG. 19.

### IV. C. Induction Motor Model

An induction motor that operates under unbalanced conditions is traditionally modeled by an iterative symmetrical component model. At each iteration, the phase motor voltage is converted into sequence quantities, from which the positive and negative sequence currents are calculated and converted back into phase quantities. An equivalent three-phase asymmetric impedance matrix can be used to model the line-to-line voltages and the line currents for a specific slip:

$$[ \begin{matrix}{\tilde{V}}_{AB} \\ {\tilde{V}}_{BC} \\ {\tilde{V}}_{CA}\end{matrix} ] = [ \begin{matrix}{\tilde{Z}}_{AA} & {\tilde{Z}}_{AB} & {\tilde{Z}}_{A C} \\ {\tilde{Z}}_{BA} & {\tilde{Z}}_{BB} & {\tilde{Z}}_{BC} \\ {\tilde{Z}}_{CA} & {\tilde{Z}}_{CB} & {\tilde{Z}}_{CC}\end{matrix} ] [ \begin{matrix}{\tilde{I}}_{A} \\ {\tilde{I}}_{B} \\ {\tilde{I}}_{C}\end{matrix} ] \qquad ( 48 )$$

This mathematically derived model, however, is known to produce an ill-conditioned impedance matrix that can result in numerical problems for power flow analysis. The genesis of this problem can be recognized from the physical representation of the corresponding circuit. Most notably, the model in Equation 53 corresponds to an equivalent circuit that contains a loop of controlled voltage sources, as shown in FIG. 20.

Any loop of ideal voltage sources is problematic for an equivalent circuit model, since the current flowing through that loop is unbounded. To address this problem, a new model was derived that follows Kirchhoff's voltage law (KVL):

\tilde{V}_{AB}+\tilde{V}_{BC}+\tilde{V}_{CA}=0 (49)

Using Gaussian elimination, the linear system in Equation 50 can be reduced to:

$$[ \begin{matrix}{\tilde{V}}_{AB} \\ {\tilde{V}}_{BC}\end{matrix} ] = [ \begin{matrix}{\tilde{Z}}_{11} & {\tilde{Z}}_{12} \\ {\tilde{Z}}_{21} & {\tilde{Z}}_{22}\end{matrix} ] [ \begin{matrix}{\tilde{I}}_{A} \\ {\tilde{I}}_{B}\end{matrix} ] \qquad ( 50 )$$

It should be noted that this corresponds to the removal of the three controlled voltage sources in FIG. 20 that are redundant. An exemplary split circuit model can be derived for an induction motor by splitting Equation 55 into real and imaginary parts:

$$[ \begin{matrix}{V}_{AB}^{R} \\ {V}_{AB}^{I} \\ {V}_{BC}^{R} \\ {V}_{BC}^{I}\end{matrix} ] = [ \begin{matrix}{R}_{11} & - {X}_{11} & {R}_{12} & - {X}_{12} \\ {X}_{11} & {R}_{11} & {X}_{12} & {R}_{12} \\ {R}_{21} & - {X}_{21} & {R}_{22} & - {X}_{22} \\ {X}_{21} & {R}_{21} & {X}_{22} & {R}_{22}\end{matrix} ] [ \begin{matrix}{I}_{A}^{R} \\ {I}_{A}^{I} \\ {I}_{B}^{R} \\ {I}_{B}^{I}\end{matrix} ] \qquad ( 51 )$$

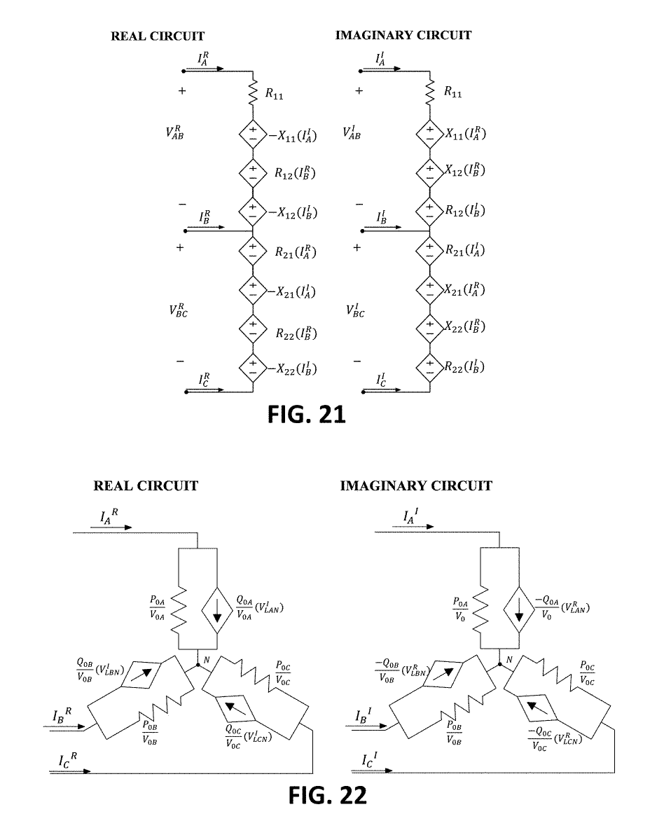

Equation 56 models the induction motor by using linear resistors and current-controlled voltage sources. FIG. 21 further shows the circuit schematic of the proposed linear model for a 3-phase induction motor.

### IV. D. Constant PQ Load Model

A nonlinear PQ load model is derived above, where the real and imaginary load currents are represented as nonlinear functions of the real and imaginary bus voltages (see Equations 12 and 13). The load model in Equations 12 and 13 can be directly applied to each phase of a 3-phase distribution system.

### IV. E. Constant Impedance Load Model

For the constant impedance load model, the real and reactive powers (P₀ and Q₀) are specified for the nominal voltage V_{L0}. The mathematical expression for modeling the bus voltage and load current is given in Equations 57 and 58:

$$\begin{matrix}{P}_{0} + {jQ}_{0} = {{\tilde{V}}_{L 0} ( \frac{{\tilde{V}}_{L 0}}{{\tilde{Z}}_{0}} )}^{*} & ( 52 ) \\ {\tilde{I}}_{L} = \frac{{\tilde{V}}_{L 0}}{{\tilde{Z}}_{0}} & ( 53 )\end{matrix}$$

Solving Equation 53 for \tilde{Z}₀, substituting it into Equation 54, and splitting the real and imaginary parts yields:

$$\begin{matrix}{I}_{L}^{R} = \frac{{P}_{0}}{{\vert {V}_{L 0} \vert}^{2}} {V}_{L}^{R} + \frac{{Q}_{0}}{{\vert {V}_{L 0} \vert}^{2}} {V}_{L}^{I} & ( 54 ) \\ {I}_{L}^{I} = \frac{- {Q}_{0}}{{\vert {V}_{L 0} \vert}^{2}} {V}_{L}^{R} + \frac{{P}_{0}}{{\vert {V}_{L 0} \vert}^{2}} {V}_{L}^{I} & ( 55 )\end{matrix}$$

Equations 59 and 60 model the constant impedance load by using an equivalent circuit with linear resistors and voltage-controlled current sources. The equivalent split circuit of an open Wye connected constant impedance load is shown in FIG. 22.

### IV. F. Ideal Center-Tapped Transformer Model

The model for a standard transformer model is derived above. However, a center-tapped transformer, as a special type of transformer, can be found as a branch element connecting buses in nearly every distribution network. The split circuit model of a center-tapped transformer can be derived by relating the primary voltage with the secondary voltage that is tapped (\tilde{V}_{A} and \tilde{V}ₐ=\tilde{V}ₐₙ+\tilde{V}_{nb}) through the turn ratios tₐₙ and t_{bn} and the phase angle θ (which is only non-zero for phase shifters):

$$\begin{matrix}\frac{{\tilde{V}}_{an}}{{\tilde{V}}_{A}} = \frac{1}{{t}_{an}} {e}^{- j θ} & ( 56 ) \\ \frac{{\tilde{V}}_{nb}}{{\tilde{V}}_{A}} = \frac{1}{{t}_{bn}} {e}^{- j θ} & ( 57 )\end{matrix}$$

After solving for the real and imaginary parts for both \tilde{V}ₐₙ and \tilde{V}_{nb}, it is possible to obtain the following secondary voltage expressions:

$$[ \begin{matrix}{V}_{an}^{R} \\ {V}_{an}^{I} \\ {V}_{nb}^{R} \\ {V}_{nb}^{I}\end{matrix} ] = [ \begin{matrix}\frac{cos θ}{{t}_{an}} & - \frac{sin θ}{{t}_{an}} & \frac{cos θ}{{t}_{bn}} & - \frac{sin θ}{{t}_{bn}} \\ \frac{sin θ}{{t}_{an}} & \frac{cos θ}{{t}_{an}} & \frac{sin θ}{{t}_{bn}} & \frac{cos θ}{{t}_{bn}}\end{matrix} ] [ \begin{matrix}{V}_{A}^{R} \\ {V}_{A}^{I}\end{matrix} ] \qquad ( 58 )$$

As can be seen from Equation 63, each of the secondary voltages can be modeled with two voltage-controlled voltage sources that are controlled by the primary voltages in the real and imaginary circuits respectively. The primary and secondary currents can be expressed in terms of the turn ratios tₐₙ and t_{bn}:

$${\tilde{I}}_{A} = - {\tilde{I}}_{an} \frac{1}{{t}_{an}} {e}^{j θ} - {\tilde{I}}_{nb} \frac{1}{{t}_{bn}} {e}^{j θ} \qquad ( 59 )$$

Splitting Equation 64 into real and imaginary parts, the following expressions for real and imaginary primary currents can be obtained:

$$[ \begin{matrix}{I}_{A}^{R} \\ {I}_{A}^{I}\end{matrix} ] = [ \begin{matrix}\frac{- cos θ}{{t}_{an}} & \frac{sin θ}{{t}_{an}} & \frac{- cos θ}{{t}_{bn}} & \frac{sin θ}{{t}_{bn}} \\ \frac{- sin θ}{{t}_{an}} & \frac{- cos θ}{{t}_{an}} & \frac{- sin θ}{{t}_{bn}} & \frac{- cos θ}{{t}_{bn}}\end{matrix} ] [ \begin{matrix}{I}_{an}^{R} \\ {I}_{an}^{I} \\ {I}_{nb}^{R} \\ {I}_{nb}^{I}\end{matrix} ] \qquad ( 60 )$$

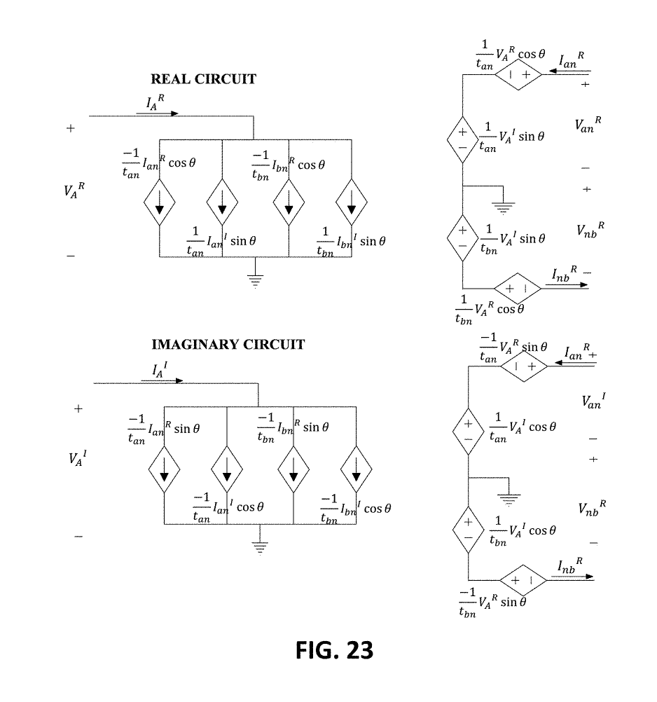

The primary currents can be modeled with four current-controlled current sources that are controlled by the currents Iₐₙ^{R}, Iₐₙ^{I}, I_{nb}^{R} and I_{nb}^{I} from the secondary side. The complete split circuit model is shown in FIG. 23.

### V. Three-Phase Power Flow Results and Discussion

The equivalent circuit models derived in the previous section were applied to the IEEE 4-bus Wye-Delta center-tapped transformer example. It is considered an extremely challenging case because the transformer connection, also known as the “4-wire delta” bank, is nontrivial to handle. Grounding the center tap shifts the secondary voltage reference to an unusual location for three-phase circuit analysis. It also results in unbalanced voltages and currents that can affect the three-phase motors and overload the transformer.

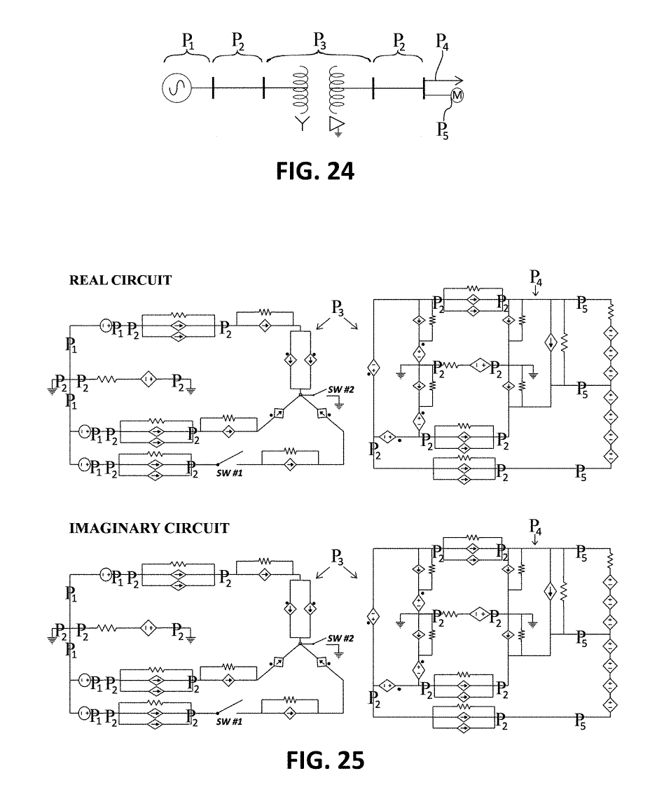

The schematic diagram of the 4-bus system with labeled elements is shown in FIG. 24. As shown, portion P₁ is a generator, portions P₂ are transmission lines, portion P₃ is a Wye-Delta center tapped transformer, portion P₄ is a single phase load (or a plurality of such loads), and portion P₅ is a 3-phase induction motor. Its equivalent split circuit model is shown in FIG. 25, with the equivalent portions P₁, P₂, and P₅ bounded by their respective labels and P₃ shown between the separate P₂ portions and P₄ shown between the right-hand P₂ portion and the P₅ portion. Two configurations of the aforementioned system were considered. Since the TLA formulation proposed hereinabove is capable of handling shorts and opens easily, ideal switches were implemented in the test case (FIG. 25). As such, by closing switch 1 and leaving switch 2 open, the first (#1) of two configurations is obtained. This configuration represents the normally operating 4-bus system with unbalanced loading and the ungrounded Wye-delta transformer bank with a center-tapped transformer in one leg of the delta secondary. The second configuration (#2) can be obtained by reversing switches 1 and 2 (i.e., switch 1 open and switch 2 closed), which represents a system that operates in the event of a failure (primary phase C fault).

A prototype circuit solver was implemented in MATLAB™ software. A graph and spanning tree were built and the TLA equations were formulated for the 4-bus test case. The TLA equations were then solved using NR. The proposed implementation successfully simulated both configurations. The iteration counts and stopping criteria based on a flat initial guess are given in Table IV.

TABLE IV
SIMULATION RESULTS FOR THREE-PHASE TEST CASES

| Configuration # | Iteration Count | Stopping Criteria |
|---|---|---|
| 1 | 3 | 1e−9 V |
| 2 | 3 | 1e−9 V |

Since most circuit elements in the split circuit model proposed herein are linear, the NR method converges quickly (after the second iteration). It is important to note that the induction motor model does not have to be solved iteratively like the traditional sequence model and is simply modeled as a combination of linear circuit elements in this formulation.

The equivalent circuit formulation has thus been extended to the 3-phase steady state analysis of distribution power grids. Preliminary results demonstrate that the proposed approach provides fast and robust convergence and is not limited to balanced loads, particular network configurations, or type of simulation. The proposed equivalent circuit and TLA approach have the ability to incorporate any electrical load (e.g., converters, solar cells, high voltage DC components, among others) effortlessly into its formulation. Furthermore, the proposed approach allows for use of unified modeling methodology to perform various power system simulations such as steady-state power flow, transient, and contingency analysis on a given network. In some cases, this simulation approach can be extended to perform steady-state and transient simulations on a given network without altering the equivalent circuit models between the two.

### VI. Harmonic Steady-State Modeling of Time-Dependent Nonlinearities

For several decades, power flow analysis based on iteratively solving the power balance equations at a single fundamental frequency has been the standard for steady-state simulation of power systems. With the emergence of new grid technologies and their corresponding reliance on power electronics and other smart grid devices, the complete simulation problem becomes more complex and mixed-domain. Due to the voltage and frequency characteristics of these nonlinear devices, a wide spectra of harmonics are induced onto a power grid, thereby making the single frequency assumption less valid. The present inventors have recognized that the harmonic balance method used to simulate distortion in radio receiver circuits can be extended to analyze the harmonics injected into the power grid due to the highly nonlinear components.

The equivalent split circuit formulation of the power flow problem with current and voltage state variables is discussed above, where it is shown that the buses, transmission lines and other power system devices can be replaced with equivalent circuit elements (voltage sources, impedances, etc.). This formulation enables the adaptation and application of circuit simulation based methods, such as harmonic balance, to accurately simulate the steady-state response even with inclusion of highly nonlinear and time varying power system components. The following subsections illustrate the derivation of exemplary harmonic balance formulations for power systems.

### VI. A. Exemplary Method of Harmonic Balance

Harmonic balance can be represented as an extension of phasor analysis from linear to nonlinear ordinary differential equations. This implies that all current and voltage state variables of the power system's equivalent circuit can be represented in the time domain by periodic, bounded, and piecewise continuous functions that satisfy the Dirichlet-Jordan criterion, and hence can be further approximated with a finite sum of harmonically related linear sinusoids in a Fourier series,

$$x [ {t}_{n} ] = {\sum }_{k = 1 - H}^{H - 1} X [ k ] ( cos ( k {ω}_{0} {t}_{n} ) + j sin ( k {ω}_{0} {t}_{n} ) ) \qquad ( 66 )$$

Where X[k]ε [symbol] , i.e. X[k]=X^{R}[k]+jX^{I}[k], represents a phasor (Fourier coefficient), H is the defined number of harmonics used to approximate the state variable defined in Equation 66, n and k are indices of time and harmonic samples, respectively, and ω₀ the fundamental frequency (usually chosen to be the frequency of the source, e.g., 60 Hz). It should be noted that if simulation of the power system's inter-harmonic components is desired, the fundamental frequency can be set to a fraction of the source frequency.

Considering that the state variable expanded in a Fourier series is constrained to be a real periodic function, the expression in Equation 66 can be further simplified, resulting in the Discrete Fourier Transform (DFT) pair given by:

$$x [ n ] = {X}^{R} [ 0 ] + 2 {\sum }_{k = 1}^{H - 1} [ {ℱ}_{[ n , k ]}^{R} {X}^{R} [ k ] - {ℱ}_{[ n , k ]}^{I} {X}^{I} [ k ] ] \qquad ( 67 )$$

$$[ \begin{matrix}{X}^{R} [ k ] \\ {X}^{I} [ k ]\end{matrix} ] = \frac{1}{S} {\sum }_{n = 0}^{S - 1} [ \begin{matrix}{ℱ}^{R} [ n , k ] \\ - ℱ [ n , k ]\end{matrix} ] x [ n ] \\ where \\ {ℱ}^{R} [ n , k ] = cos ( \frac{2 π kn}{S} ) , {ℱ}^{I} [ n , k ] = sin ( \frac{2 π kn}{S} ) , and S = 2 H - 1. \qquad ( 68 )$$

The method of harmonic balance represents a mixed domain analysis that combines the advantages of nonlinear time-domain device modeling with the efficiency of steady state frequency domain analysis. From the perspective of equivalent circuit modeling, this method can be seen as solving the DC and H−1 complex mutually coupled circuits. Similar to the formulations above, these H−1 complex equivalent circuits would themselves be split into 2(H−1) sub-circuits: H−1 real, and H−1 imaginary, coupled by controlled sources. By splitting the circuit, its equations are no longer complex and, hence, the Newton-Raphson (NR) method can be used to solve the nonlinear equations with quadratic convergence.

In order to derive the generalized formulation for the aforementioned mixed domain algorithm, let y(t) be a highly nonlinear time-dependent function of x(t) with no closed form continuous transformation to the frequency domain:

y(t)=f(x(t)) (69)

To obtain the frequency response of the function given in Equation 69, the state variable spectrum that is to be applied, X[ω]=X^{R}[ω]+−jX^{I}[ω], is transformed into the time domain using the DFT in Equation 67. It is then applied to the nonlinear function whose resulting response is transformed back into the frequency domain using Equation 68. The generalized formulation for obtaining the m^{th} harmonic of the frequency domain function, Y[ω], is given in Equation 70, and such will be further used in deriving the steady-state models of nonlinear power electronic devices:

$$\begin{matrix}[ \begin{matrix}{Y}^{R} [ m ] \\ {Y}^{I} [ m ]\end{matrix} ] = \frac{1}{S} {\sum }_{n = 0}^{S - 1} [ \begin{matrix}{ℱ}^{R} [ m , k ] \\ - {ℱ}^{I} [ m , k ]\end{matrix} ] f [ γ ] & ( 70 ) \\ \text{where:} & \\ γ = ξ {\sum }_{k = 0}^{H - 1} {ℱ}^{R} [ n , k ] {V}_{D}^{R} [ k ] - {ℱ}^{I} [ n , k ] {V}_{D}^{I} [ k ] & ( 71 )\end{matrix}$$

for ζ=2−δ(k) and Kronecker delta function defined as:

$$δ ( k ) = \{ \begin{matrix}1 & if k = 0 \\ 0 & if k \neq 0\end{matrix}$$

### VI. B. Steady-State Modeling of Time Dependent Nonlinearities

The section illustrates applying the method of harmonic balance to derive steady-state models of a diode and a nonlinear inductor to illustrate power electronic device modeling.

VI. B. i. Steady-State Model of a Diode

A diode represents a key component in many power electronic devices. The diode current is an exponential function of the voltage across the diode given by:

i_{D}(t)=Iₛₐₜ(e^{a}^{ₜₕ}^{v}^{_{D}}^{(t)}−1) (72)

where Iₛₐₜ represents the reverse saturation DC current, (typically ≈10 nA), αₜₕ a constant equal to the reciprocal of the thermal voltage multiplied by a non-ideality factor, and V_{D}(t) the time-varying voltage across the diode.

From the perspective of equivalent circuit modeling, Equation 72 can be seen as a nonlinear time dependent element in parallel with the linear independent DC saturation current source, as shown in FIG. 30. The nonlinear diode model given in Equation 72 represents an exponential function that can be expanded in an infinite series, yielding an infinite number of harmonics. However, depending on the device that is to be analyzed, there will be H dominant harmonics that can accurately represent the signal. Only these H harmonics will be further considered; all other harmonics will be neglected.

The steady-state equivalent circuit model of a diode is obtained by converting the time domain equivalent circuit in FIG. 30 to the steady-state DC and H−1 real and H−1 imaginary equivalent circuits, harmonically coupled by controlled sources. Using the formulation from Equation 70, the nonlinear functions of real and imaginary diode steady-state currents are found and given for the m^{th} harmonic by:

$$[ \begin{matrix}{I}_{d}^{R} [ m ] \\ {I}_{d}^{I} [ m ]\end{matrix} ] = \frac{1}{S} {\sum }_{n = 0}^{S - 1} [ \begin{matrix}{ℱ}^{R} [ m , k ] \\ - {ℱ}^{I} [ m , k ]\end{matrix} ] exp ( {γ}_{D} ) \qquad ( 73 )$$

where γ_{D} is given by:

$${γ}_{D} = {ξα}_{th} {\sum }_{k = 0}^{H - 1} {ℱ}^{R} [ n , k ] {V}_{D}^{R} [ k ] - {ℱ}^{I} [ n , k ] {V}_{D}^{I} [ k ] \qquad ( 74 )$$

The nonlinear harmonic diode current functions, such as the ones presented in Equation 73, are linearized via a first order Taylor expansion in order to obtain the linearized circuit equivalent. For example, the Taylor expansion of the real m^{th} harmonic current about the (s+1)^{th} iteration is given by:

$${I}_{{d}_{[ m ]}}^{{R}^{( s + 1 )}} = {I}_{{d}_{[ m ]}}^{{R}^{( s )}} - {\sum }_{i = 0}^{H - 1} {X}_{d}^{R} ( [ \begin{matrix}{V}_{{d}_{[ i ]}}^{{R}^{( s )}} \\ {V}_{{d}_{[ i ]}}^{{I}^{( s )}}\end{matrix} ] + [ \begin{matrix}{V}_{{d}_{[ i ]}}^{{R}^{( s + 1 )}} \\ {V}_{{d}_{[ i ]}}^{{I}^{( s + 1 )}}\end{matrix} ] ) \qquad ( 75 )$$

where m, iε{0,H−1} and X_{d}^{R} is a row vector defined by:

$${X}_{d}^{R} = [ {( \frac{\partial {I}_{{d}_{[ m ]}}^{R}}{\partial {V}_{{d}_{[ i ]}}^{R}} )}_{\vert {V}_{d}^{{R}^{( s )}} , {V}_{d}^{{I}^{( s )}}}^{( s )} {( \frac{\partial {I}_{{d}_{[ m ]}}^{R}}{\partial {V}_{{d}_{[ i ]}}^{I}} )}_{\vert {V}_{d}^{{R}^{( s )}} , {V}_{d}^{{I}^{( s )}}}^{( s )} ] \qquad ( 76 )$$

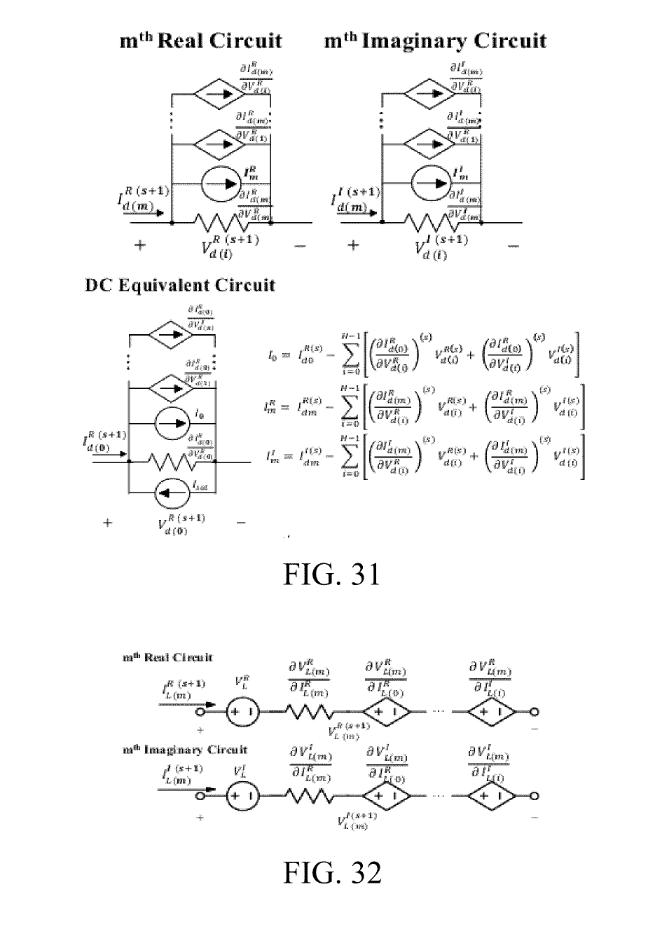

The first two terms of Equation 75 are dependent on known values from the previous iteration and can therefore be lumped together and represented as an independent current source. A subterm of the third term in Equation 75, where the m^{th} real harmonic current is proportional to the m^{th} real voltage of the spectrum, i.e., m=i, is represented by a conductance, while the other subterms represent a voltage-controlled current source, where the real m^{th} harmonic current is proportional to the other real and imaginary harmonic voltages. Combining these elements represents the complete steady-state equivalent model of a diode, with the DC and m^{th} harmonic circuit as shown in FIG. 31. It is noted that there are H−2 more real and imaginary equivalent circuits symmetric to the m^{th} harmonic circuit illustrated in FIG. 31.

VI. B. ii. Steady-State Model of a Nonlinear Inductor

In the design of power-magnetic devices, such as transformers and induction motors, the internal magnetic circuits are usually designed to operate at the knee point of the B-H curve. The saturation of magnetic core material yields the nonlinear relationship between magnetic flux and the current, thereby causing the higher harmonics to be injected into the grid.

A nonlinear inductor model that accurately captures the saturation of the magnetic core material and is dependent on the B-H curve of the magnetic material can be derived from the nonlinear time domain relationship between the magnetic flux and inductor current:

$$\begin{matrix}ϕ ( {i}_{L} ) = {A}_{e} {B}_{sat} tanh ( \frac{{aN}_{w}}{{l}_{e}} {i}_{L} ( t ) ) & ( 77 ) \\ \text{where:} & \\ a = \frac{{μ}_{0} {μ}_{r}}{{B}_{0}} {tanh}^{- 1} ( \frac{{B}_{0}}{{B}_{sat}} ) & ( 78 )\end{matrix}$$

Aₑ is the magnetic core cross-sectional area, Bₛₐₜ the magnetic field density at which the core is fully saturated, N_{w} the number of windings, lₑ the effective magnetic core length, μ₀ the permeability of free space, μᵣ the relative permeability of the magnetic core, given as 3000 for the magnetic field density at which the core starts saturating B₀=0.75 T, obtained from B-H curve.

The time domain function of voltage across the nonlinear inductor is then obtained from Faraday's law of induction:

$${v}_{L} ( t ) = - \frac{d}{dt} [ {A}_{e} {B}_{sat} tanh ( \frac{{aN}_{w}}{{l}_{e}} {i}_{L} ( t ) ) ] \qquad ( 79 )$$

In order to derive the steady-state model of a nonlinear inductor, its time domain governing equation is transformed to the frequency domain. The real and imaginary steady-state voltage across the inductor for the m^{th} harmonic voltage are given by:

$$[ \begin{matrix}{V}_{L}^{R} [ m ] \\ {V}_{L}^{I} [ m ]\end{matrix} ] = \frac{{α}_{L} {ω}_{0}}{S} {\sum }_{n = 0}^{S - 1} k [ \begin{matrix}- {ℱ}^{l} [ m , k ] \\ {ℱ}^{R} [ m , k ]\end{matrix} ] tanh ( {γ}_{L} ) \qquad ( 80 )$$

where α_{L}=−AₑBₛₐₜ and γ_{L} is defined as:

$${γ}_{L} = ξ \frac{{aN}_{w}}{{l}_{e}} {\sum }_{k = 0}^{H - 1} {ℱ}^{R} [ n , k ] {I}_{L}^{R} [ k ] - {ℱ}^{I} [ n , k ] {I}_{L}^{I} [ k ] \qquad ( 81 )$$

Similar to the steady-state modeling of a diode, first order Taylor expansions of the harmonic voltage equations in Equation 80 are then taken to linearize the functions and derive the equivalent circuit components. As shown in FIG. 32, the linearized steady-state m^{th} harmonic equivalent circuit of a nonlinear inductor consists of independent voltage sources V_{L}^{R}, V_{L}^{I}, which represent the lumped terms dependent on values from the previous iteration, a resistor where the m^{th} real/imaginary harmonic voltage is proportional to the m^{th} real/imaginary current of the spectrum, and current-controlled voltage sources, where the m^{th} harmonic currents are proportional to the other real and imaginary harmonic voltages. It is noted that at k=0, i.e., DC component, an inductor equivalent circuit is simply a short circuit.

### VI. C. Steady-State Modeling of Power System Components

VI. C. i. Slack Bus

In conventional modeling of power systems, a slack bus generally represents a reference generator at the transmission level or an aggregated equivalent of the transmission grid at distribution level. Furthermore, it is assumed that the generator operates at the source frequency (e.g., 60 Hz). Per phase and three-phase equivalent circuit models of a slack bus are derived above. To obtain the harmonic equivalent circuit, the slack bus frequency domain voltage is found by applying the DFT from Equation 68:

$${V}_{s}^{R} [ k ] + {jV}_{s}^{I} [ k ] = \{ \begin{matrix}\frac{{V}_{r}}{\sqrt{2}} ( cos {ϕ}_{V} + j sin {ϕ}_{V} ) & if k = 1 \\ 0 , & if k \neq 1\end{matrix} \qquad ( 82 )$$

where φ_{V} is a respective voltage angle, Vᵣ an RMS phase voltage, and k=1 a harmonic index related to the source frequency.

As implied by Equation 82 a slack bus generator can be modeled as independent voltage sources of values

$$\frac{{V}_{r}}{\sqrt{2}} cos {ϕ}_{V } and \frac{{V}_{r}}{\sqrt{2}} sin {ϕ}_{V}$$

in the real and imaginary circuits related to the source frequency. Further, it is replaced by a short in all other harmonic equivalent split-circuits. If desired, source harmonics can also be incorporated and result in additional independent voltage sources in the harmonic split circuit equivalents related to the considered harmonics.
VI. C. ii. Transmission Line

An equivalent split circuit of a balanced transmission line at fundamental frequency is derived above. The transmission line model for each harmonic split circuit is obtained by considering the series reactance and shunt susceptance calculated using the frequency of the respective harmonic circuit. The values of line reactance and susceptance are found from Equations 83 and 84:

X_{s,k}=kω₀Lₛ (83)

B_{sh,k}=kω₀Lₛₕ (84)

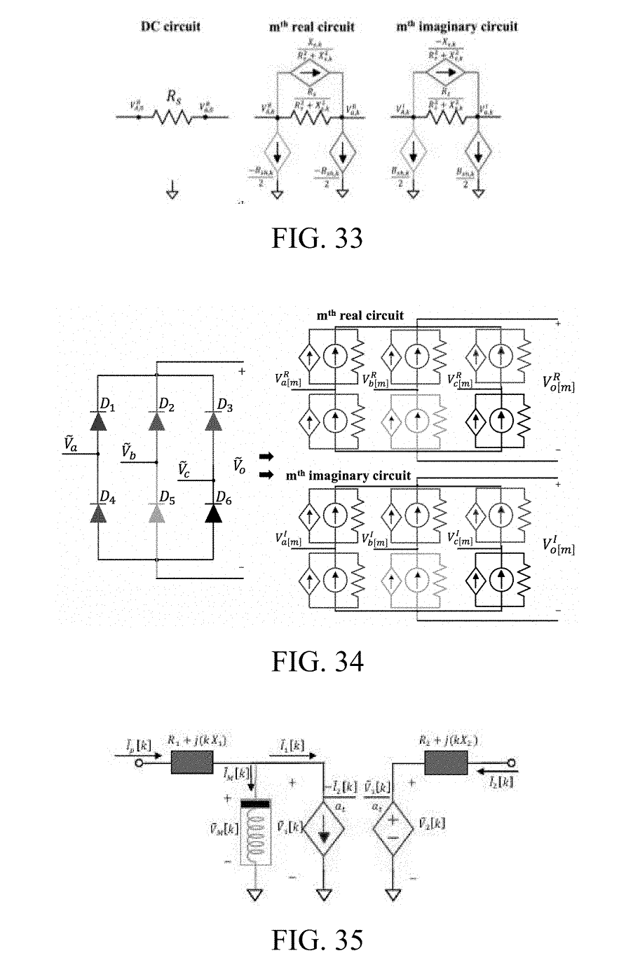

FIG. 33 illustrates a DC and m^{th} harmonic transmission line equivalent split circuit, with the controlled sources labeled to indicate coupling. There are H−2 more real and imaginary equivalent circuits symmetric to the m^{th} one illustrated herein.

VI. C. iii. PV and PQ Bus Models

The conventional power flow analysis models generator and load buses using ad-hoc real and reactive average power variables, i.e. PV and PQ buses. Above, it is shown that these bus types can be modeled as an equivalent circuit comprised of nonlinear voltage-controlled current sources. However, in studying the harmonic steady-state response of the power system, the real and reactive average power variables are shown to be a drawback in modeling of conventional PV and PQ bus types due to their non-physics based nature.

The harmonic equivalent split-circuit of a PV bus is obtained under the assumption that the generator bus operates at the single source frequency. Real and imaginary split circuits related to the source frequency are modeled as the linearized equivalents consisting of an independent voltage source, a conductance, and a voltage-controlled current source as derived above. The PV bus equivalent in all other harmonic split-circuits is replaced by a short circuit. On the other hand, the harmonic equivalent circuit of a PQ load cannot be directly incorporated into harmonic steady-state simulation framework. This is because the real and reactive powers represent the total time average powers, which are valid only in the case when the system operates at a fundamental frequency. Furthermore, due to multiple different harmonics present in current and voltage state variables, the expression of instantaneous power becomes more complex and consists of non-zero inter-harmonic terms, which makes the traditionally estimated total time average powers less valid. Approximations of the PQ model, such as conversion to constant impedance under the assumption of nominal bus voltage, can tackle this problem, but often yield inaccurate results. This indicates that an alternative physics-based load model, tuned with measurement data, could be used for further efficient steady-state analysis of the smart grid.

VI. C. iv. Three-Phase Full Bridge Rectifier

The steady-state model of a three-phase full bridge rectifier consisting of six diodes is obtained by replacing each diode with its steady-state equivalent derived in Section III. FIG. 34 shows the equivalent steady-state circuit for the m^{th} harmonic. It is noted that the controlled sources are lumped together for each diode. Moreover, the complete model consists of a DC and H−2 more real and imaginary circuits symmetric to the one presented herein.

VI. C. v. Transformer

The ideal per phase and three-phase transformer equivalent circuits are derived above. The proposed harmonic steady-state analysis enables the incorporation of the transformer's magnetic core saturation characteristics, which represent a source of harmonics injected into the power grid. This is achieved by replacing the linear inductor of magnetic core losses in a transformer model with a nonlinear saturation inductance, whose steady-state model is derived in Section V.B.ii. The per-phase transformation model that incorporates the magnetic core saturation is then given by FIG. 35.

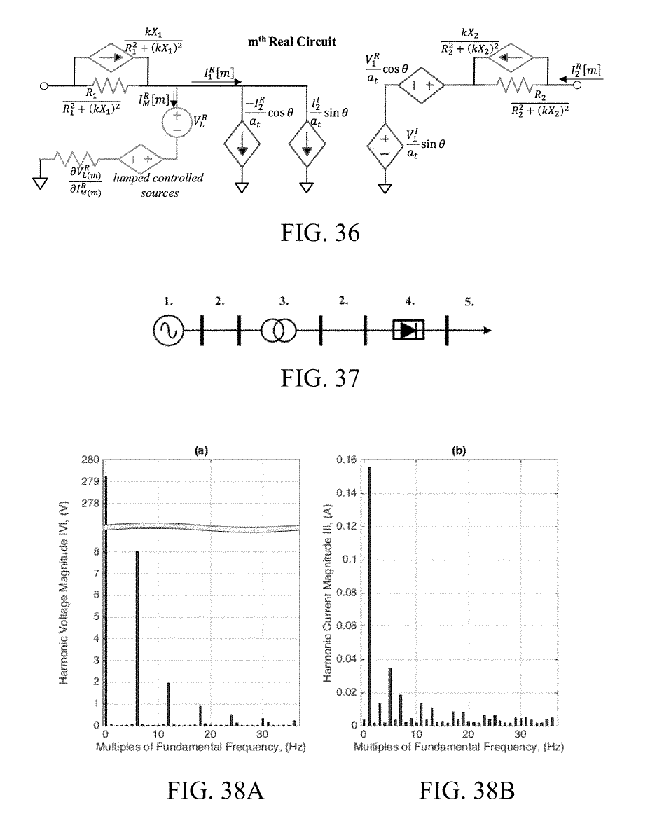

After splitting and linearizing the harmonic transformer circuit from FIG. 35, the m^{th} harmonic real circuit is given in FIG. 36. It is noted that the controlled sources of the nonlinear inductor are lumped together. In addition, the complete harmonic split circuit contains H−1 symmetrical real and imaginary split circuits, where the DC one represents a short circuit.

### VI. D. Harmonic Steady-State Analysis

VI. D. i. Generating Circuit Equations

As in the source frequency steady state split-circuit analysis discussed above, MNA or TLA can be used to solve the complete power system equivalent circuit. For TLA, a “tree” is formed by selecting elements to touch all circuit nodes and form no loops, and the harmonic voltages are solved for across these elements; all other elements comprise the “links,” and their harmonic currents are solved for. Furthermore, it can be said that the harmonic steady-state analysis of the grid represents the expansion of a source frequency analysis, which can be seen as solving a DC and H−1 mutually coupled harmonic real and imaginary circuits, using the Newton Raphson method, which ensures quadratic convergence.

VI. D. ii. Continuation Methods

Because the power electronic and smart-grid components contain highly nonlinear circuit elements, the homotopy and continuation methods are even more important to ensure robust convergence. The power stepping and Tx stepping approaches described above can be applied here as well.

### VI. E. Exemplary Results

As a demonstration of the proposed harmonic steady-state analysis, the equivalent circuit models derived in the previous sections were applied to a multi-bus power system, whose line schematic diagram is given in FIG. 37. The test case in FIG. 37. consists of a three phase wye-connected slack bus (1.) with a line-line voltage magnitude of 2.2 kV, two cable lines (2.) with a series impedance of 1+j(k1.5)Ω, a wye-wye step down magnetic core saturation transformer with turns ratio of 10 (3.), and a three-phase full bridge rectifier with a capacitor filter of 1 μF (4.), which converts AC to DC and feeds a 1 kΩ DC load (5.). The transformer data is given in Table V, below.

TABLE V
PER-PHASE TRANSFORMER PARAMETERS

| Primary Losses (R₁ + j kX₁) | Secondary Losses (R₂ + j kX₂) |
|---|---|
| 12.5 + j k28 [Ω] | 0.07 + j k0.04 [Ω] |
| Magnetic coefficient | Magnetic coefficient 2 |
| (α_{L} = AₑBₛₐₜ) | $( {τ}_{M} = \frac{α {N}_{w}}{{l}_{e}} )$ |
| 2.4 × 10⁻⁵ [Wb] | 0.8628 [A⁻¹] |

The steady-state response of the power system is obtained using the SUGAR tool noted above. A graph and spanning tree of the system's complete harmonic equivalent circuit were built, and the TLA equations were formulated and solved for harmonic voltage and current state variables using Newton-Raphson. The power stepping algorithm with scaling factor of λ=0.05 was used to ensure robust convergence for this example. The proposed implementation successfully simulated the steady-state response of the test case for the first 36 harmonics, converging in 11 iterations. The harmonic spectra of the voltage across the DC load and the current in the cable line that connects the rectifier and the transformer are given in FIGS. 38A and 38B.

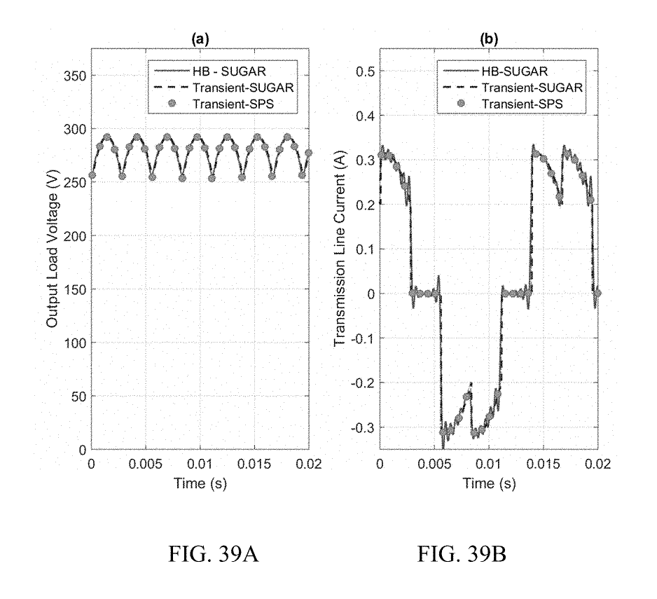

To validate the obtained harmonic steady-state results, the calculated harmonic spectra of load voltage and line A current are used to find the respective time domain waveforms from Equation 67. The waveforms are then compared with the waveforms obtained from the SUGAR transient simulation as well as SimscapePowerSystems™ (SPS) from MATLAB™, and are given in FIGS. 39A and 39B. The waveforms generated by the proposed method match with the ones from the transient simulations. The small deviations can be attributed to the Gibbs phenomenon caused by using a finite number of harmonics to represent the state variable signal in the proposed approach.

### VII. Exemplary, Nonlimiting Applications

With tree-link circuit analysis, for example, it is trivial to model both short- and open-circuit elements. This can enable more efficient contingency analysis, where it may be necessary to simulate a short or open between any two nodes in the event of a failure. Replacing lines with shorts or opens does not require the entire problem to be reformulated; only local changes to the tree are required. Sensitivity analysis methods borrowed from the circuit simulation community can also be applied to the equivalent circuit models for the power grid to perform optimal power flow analysis, optionally making use of one or more optimization algorithms, which may include formulating and solving current and voltage conservation equations described herein for optimal power flow via the optimization algorithm. Various systems, methods, and software disclosed herein may be used to simulate, analyze and operate an electrical power system, which may include performing real-time power flow scheduling and management, monitoring, controlling, planning, designing, or both planning and designing the electrical power system in accordance with a steady-state solution arrived at using aspects of the present disclosure, and/or diagnosing problems or potential problems of the electrical power system in accordance with a steady-state solution arrived at using aspects of the present disclosure.

Further embodiments of operating an electrical power system may include generating a set of switch and/or other component configurations to run the system optimally, automatically interfacing with controls on the grid, and/or providing power injections. Still further embodiments of operating an electrical power system may include minimizing power losses, minimizing generation costs, and/or generating a file specifying configurations and/or operating conditions of one or more components of the electrical power system in accordance with a steady-state solution arrived at using aspects of the present disclosure. Such configurations and operating conditions may be manually or automatically imposed on one or more of the electrical power system components. Perhaps most importantly, since any element that can be expressed in terms of voltages and currents (e.g., converters, solar cells, or high voltage DC components) can be incorporated into the equivalent circuit, this circuit-based unification of models can enable powerful new capabilities for modeling, analyzing and monitoring smart grids. Further, aspects of the present disclosure can be used to plan, design, or both plan and design new electrical power systems, which may include generating a file specifying configurations and/or operating conditions of one or more components. For example, a requisite or optimal selection of available generators, required voltage magnitude and/or output power of generators, number of transmission lines, requisite or optimal voltage and/or current ratings of transmission lines and/or generators, and/or maximum loadability (i.e., how much power the system will be able to provide before failure) can be determined, either for a new or existing power system, using aspects of the present disclosure. These and various other applications of the inventive concepts disclosed in the present disclosure will readily be able to be implemented by one of ordinary skill in the electrical power planning, simulation, generation, transmission, and/or distribution arts, among others, without undue experimentation after reading this disclosure in its entirety.

### VIII. Exemplary, Nonlimiting Computing Environment

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

FIG. 26 shows a diagrammatic representation of one embodiment of a computing device in the exemplary form of a computer system 2600 within which a set of instructions for causing a control system, such as any one or more of the systems and/or components described herein, to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 2600 includes a processor 2604 and a memory 2608 that communicate with each other, and with other components, via a bus 2612. Bus 2612 may include any of several types of bus structures including, but not limited to, a memory bus, a memory controller, a peripheral bus, a local bus, and any combinations thereof, using any of a variety of bus architectures.

Memory 2608 may include various components (e.g., machine-readable media) including, but not limited to, a random access memory component, a read only component, and any combinations thereof. In one example, a basic input/output system 2616 (BIOS), including basic routines that help to transfer information between elements within computer system 2600, such as during start-up, may be stored in memory 2608. Memory 2608 may also include (e.g., stored on one or more machine-readable media) instructions (e.g., software) 2620 embodying any one or more of the aspects and/or methodologies of the present disclosure. In another example, memory 2608 may further include any number of program modules including, but not limited to, an operating system, one or more application programs, other program modules, program data, and any combinations thereof.

Computer system 2600 may also include a storage device 2624. Examples of a storage device (e.g., storage device 2624) include, but are not limited to, a hard disk drive, a magnetic disk drive, an optical disc drive in combination with an optical medium, a solid-state memory device, and any combinations thereof. Storage device 2624 may be connected to bus 2612 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 2624 (or one or more components thereof) may be removably interfaced with computer system 2600 (e.g., via an external port connector (not shown)). Particularly, storage device 2624 and an associated machine-readable medium 2628 may provide nonvolatile and/or volatile storage of machine-readable instructions, data structures, program modules, and/or other data for computer system 2600. In one example, software 2620 may reside, completely or partially, within machine-readable medium 2628. In another example, software 2620 may reside, completely or partially, within processor 2604.

Computer system 2600 may also include an input device 2632. In one example, a user of computer system 2600 may enter commands and/or other information into computer system 2600 via input device 2632. Examples of an input device 2632 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 2632 may be interfaced to bus 2612 via any of a variety of interfaces (not shown) including, but not limited to, a serial interface, a parallel interface, a game port, a USB interface, a FIREWIRE interface, a direct interface to bus 2612, and any combinations thereof. Input device 2632 may include a touch screen interface that may be a part of or separate from display 2636, discussed further below. Input device 2632 may be utilized as a user selection device for selecting one or more graphical representations in a graphical interface as described above.

A user may also input commands and/or other information to computer system 2600 via storage device 2624 (e.g., a removable disk drive, a flash drive, etc.) and/or network interface device 2640. A network interface device, such as network interface device 2640, may be utilized for connecting computer system 2600 to one or more of a variety of networks, such as network 2644, and one or more remote devices 2648 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 2644, may employ a wired and/or a wireless mode of communication. In general, any network topology may be used. Information (e.g., data, software 2620, etc.) may be communicated to and/or from computer system 2600 via network interface device 2640.

Computer system 2600 may further include a video display adapter 2652 for communicating a displayable image to a display device, such as display device 2636. Examples of a display device include, but are not limited to, a liquid crystal display (LCD), a cathode ray tube (CRT), a plasma display, a light emitting diode (LED) display, and any combinations thereof. Display adapter 2652 and display device 2636 may be utilized in combination with processor 2604 to provide graphical representations of aspects of the present disclosure. In addition to a display device, computer system 2600 may include one or more other peripheral output devices including, but not limited to, an audio speaker, a printer, and any combinations thereof. Such peripheral output devices may be connected to bus 2612 via a peripheral interface 2656. Examples of a peripheral interface include, but are not limited to, a serial port, a USB connection, a FIREWIRE connection, a parallel connection, and any combinations thereof.

### IX. Scope of Invention

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A method, comprising:
formulating, in a power flow analyzer and for an electrical power system, current and voltage conservation equations from which power flows, currents, and voltages can be derived, wherein the current and voltage conservation equations correspond to an equivalent circuit representation of the electrical power system that includes:
a real sub-circuit including all real-valued voltages and currents; and
an imaginary sub-circuit containing all imaginary-valued voltages and currents,
wherein the real sub-circuit and imaginary sub-circuit are coupled via controlled voltage and current sources; and
causing the power flow analyzer to solve the current and voltage conservation equations so as to produce a steady-state solution for the power flows, currents, and voltages for the electrical power system.

2. The method according to claim 1, wherein the current and voltage conservation equations include a governing equation for a component of the electrical power system.

3. The method according to claim 2, wherein the governing equation represents a complex voltage magnitude for a generator in the electrical power system.

4. The method according to claim 1, wherein components of the electrical power system can be described by combinations of linear and nonlinear equations, the method further comprising deriving representative current and voltage equations from the combinations of linear and nonlinear equations.

5. The method according to claim 4, wherein the combinations of linear and nonlinear equations represent a nonlinear current-voltage characteristic of a solar array.

6. The method according to claim 4, wherein the combinations of linear and nonlinear equations represent a nonlinear current-voltage characteristic of a wind generator.

7. The method according to claim 4, further comprising performing a transient analysis of the electrical power system as a function of the combinations of linear and nonlinear equations.

8. The method according to claim 1, further comprising formulating the current and voltage conservation equations in terms of nodal or modified nodal analysis equations.

9. The method according to claim 1, further comprising performing state estimation of the electric power system based on traditionally and newly deployed measurements obtained from in particular but not limited to smart meters and power electronic devices.

10. The method according to claim 1, further comprising formulating the current and voltage conservation equations in terms of tree-link analysis equations, cutset equations derived from tree-link analysis equations, or both tree-link analysis equations and cutset equations derived from tree-link analysis equations.

11. The method according to claim 10, further comprising performing a contingency analysis of the electrical power system as a function of a representation of changing values in the equivalent circuit representation, the values being derived from the tree-link analysis equations, the cutset equations, or both the tree-link analysis equations and the cutset equations.

12. The method according to claim 1, wherein solving the current and voltage conservation equations to produce a steady-state solution includes producing a steady-state solution for a single phase of the electrical power system.

13. The method according to claim 1, wherein solving the current and voltage conservation equations to produce a steady-state solution includes concurrently producing steady-state solutions for two or more phases of the electrical power system.

14. The method according to claim 1, wherein the current and voltage conservation equations include equations for formulating and solving for optimal power flow via an optimization algorithm, the method further comprising formulating and solving the equations for optimal power flow via the optimization algorithm.

15. The method according to claim 1, further comprising automatedly performing real-time power flow scheduling and management in accordance with the steady-state solution.

16. The method according to claim 1, further comprising automatedly planning, designing, or both planning and designing, the electrical power system in accordance with the steady-state solution.

17. The method according to claim 1, further comprising automatedly diagnosing problems or potential problems of the electrical power system in accordance with the steady-state solution.

18. The method according to claim 1, further comprising minimizing power losses in accordance with the steady-state solution.

19. The method according to claim 1, further comprising minimizing generation costs in accordance with the steady-state solution.

20. The method according to claim 19, further comprising generating a file specifying configurations and operating conditions of one or more components of the electrical power system in accordance with the steady-state solution.

21. The method according to claim 20, wherein the configurations and operating conditions of the one or more components of the electrical power system generated in accordance with the steady-state solution are automatically imposed on one or more components of the electrical power system.

22. The method according to claim 1, wherein the current and voltage conservation equations have a solution space and the steady-state solution to the current and voltage conservation equations is achieved while using a variable limiting method to restrict the solution space.

23. The method according to claim 1, wherein the current and voltage conservation equations are formulated into an initial problem to be solved, and solution to the current and voltage conservation equations is achieved via power stepping in which a good trivial solution is first obtained by decreasing non-linearities in the initial problem and then subsequently taking incremental steps back to solve the initial problem.

24. The method according to claim 1, wherein the current and voltage conservation equations are formulated into an initial problem to be solved and solution to the current and voltage conservation equations is achieved via transmission line stepping in which a first trivial solution is obtained by solving a system that is based on modifying governing equations of transmission line and transformer models and then subsequently taking incremental steps back to solve the initial problem.

25. The method according to claim 24, wherein convergence of the steady-state solution to a high voltage solution is guaranteed, and a low voltage solution for non-linear conservation equations corresponding to power flow within the electrical power system is avoided.

26. The method according to claim 1, wherein all current and voltage state variables of the electrical power system are represented in the current and voltage conservation equations by a finite sum of harmonically related linear sinusoids of a Fourier series, the method further comprising solving the current and voltage conservation equations in a frequency domain for a chosen number of harmonics to generate a frequency domain solution.

27. The method in claim 26, further comprising converting the frequency domain solution to a time domain to evaluate nonlinearities at each harmonic frequency.

28. The method in claim 26, further comprising evaluating a finite number of harmonics, H, by solving a mathematical equivalent of 2(H−1) sub-circuits, each of which being represented by the equivalent circuit representation.

29. A machine-readable storage medium containing machine-executable instructions for performing any of the methods of claims 1 through 28.
